(19) United States
(12) Patent Application Publication
(10) Pub. No.: US 2015/0285923 A1
(43) Pub. Date: Oct. 8, 2015

(54) RADIATION DETECTOR AND RADIATION DETECTOR MANUFACTURING METHOD

(71) Applicant: SHIMADZU CORPORATION, Kyoto-shi (JP)

(72) Inventor: Hiromichi TONAMI, Kyoto-shi (JP)

(73) Assignee: SHIMADZU CORPORATION, Kyoto-shi (JP)

(21) Appl. No.: 14/170,245

(22) Filed: Jan. 31, 2014

(30) Foreign Application Priority Data
Feb. 8, 2013 (JP) 2013-023539

(51) Int. Cl. G01T 1/24; G01T 1/29; G01R 33/48; H01L 31/115; H01L 31/0232; G01T 1/20; H01L 31/18

(52) U.S. Cl. CPC G01T 1/244; G01T 1/2002; G01T 1/2985; G01T 1/249; G01T 1/248; H01L 31/18; H01L 31/115; H01L 31/02327; H01L 31/02325; G01R 33/481

(57) ABSTRACT

In a radiation detector, gap portions and opening portions are filled with a high-viscosity adhesive agent to prevent inclusion of air bubbles in a first adhesive layer and a second adhesive layer. The result is that scintillator light is not scattered by air bubbles, making it possible to obtain more accurate imaging information. Moreover, since the inclusion of air bubbles is prevented, it is possible to avoid weakening of the optical couplings in the radiation detector. Consequently, the optical couplings do not become weakened in the radiation detector that includes an SiPM element that is provided with gap portions. Because the SiPM element is not affected by the strong magnetic fields that are produced by the MR device, the radiation detector can be used in a PET-MR. This enables the achievement of a PET-MR having a radiation detector wherein the optical coupling is more secure.

### CROSS-REFERENCE TO RELATED APPLICATION

The present application claims priority from Japanese patent application No. 2013-023539 filed on Feb. 8, 2013, the entire contents of which are hereby incorporated by reference.

### TECHNICAL FIELD

The present disclosure relates to a radiation detector used in a positron emission tomography-magnetic resonance tomography compound device for obtaining simultaneously a nuclear medical image and a magnetic resonance image.

### BACKGROUND

Conventionally, positron emission tomography (PET) has been known as a medical imaging technique. A positron emission tomography device, that is, a “PET” device is a device that produces a PET image that shows the distribution, within the body of the subject, of a radioactive drug that is marked with a positron emitting nuclide.

As illustrated in FIG. 22, a PET device 41 is provided with a plurality of radiation detectors 43 that are disposed so as to encircle, in a ring shape, the subject body M. The radioactive drug that is injected into the subject body accumulates in the location of interest and positrons are emitted from the drug that has accumulated. The positrons that have been emitted undergo pair annihilation with electrons, producing two γ rays for each individual positron, that is, a γ ray N1 and a γ ray N2 are emitted. The γ ray N1 and the γ ray N2 have mutually opposing momenta, and thus are emitted in mutually opposite directions, and are detected simultaneously by respective radiation detectors 43.

Given this, the position wherein the pair annihilation occurred, that is, the position of the radioactive drug, is calculated based on the γ ray information that is detected, and accumulated as position information. Given this, an image that displays the distribution of the radioactive drug in the part of interest, based on the position information that is accumulated, is provided by the PET device.

The structure of a radiation detector 51 that is used commonly in a PET device will be explained with reference to FIG. 23. The radiation detector 51 has a scintillator block 53, a light guide 55, and a solid-state photodetector 57, layered in that order. The scintillator block 53 has scintillators 59 disposed two-dimensionally, separated by optical reflecting materials, to absorb the γ rays that are emitted from the subject body, to thereby emit light. Note that the light that is emitted by the scintillator 59 is defined as scintillator light. A light guide 55 optically couples the scintillator block 53 to the respective solid-state photodetector 57, to transmit the scintillator light to the solid-state photodetector 57. The solid-state photodetector 57 uses a photoelectron multiplier tube, for example, as one example of a light detecting element, to detect and convert into an electric signal the scintillator light that is transmitted by the light guide 55. Given this, a slice image that shows the distribution of the positron emitting nuclides in the part of interest is produced based on the electric signals that have been converted. In this way, images that are well-suited for diagnostics of biochemical interactions and of physiological functions are obtained through the PET device for specific organs, tumors, or the like.

On the other hand, a magnetic resonance tomography device (an MR device) is known as a medical imaging device, along with the PET device, where the image obtained by the MR device is well suited to anatomical diagnostics. In recent years, attempts have been made to combine magnetic resonance tomography devices (MR devices) with PET devices, to produce a positron emission tomography-magnetic resonance tomography compound device (PET-MR) in order to obtain images that are well-suited to both physiological diagnostics and anatomical diagnostics.

However, because the photoelectron multiplier tube used in the conventional radiation detector is susceptible to the effect of the magnetic field that is produced by the MR device, it has not been possible to use, in a PET-MR, a radiation detector that is equipped with a photoelectron multiplier tube.

Given this, the focus has been on elements known as SiPMs (silicon photomultipliers) and APDs (avalanche photodiodes), instead of the photoelectron multiplier tube. SiPM elements and APD elements are not effected by the strong magnetic fields that are produced by the MR device, so there have been reports of PET-MR that use APD elements, or the like, as the photodetecting elements (see, e.g., Published Japanese Translation of a PCT Application Originally filed in English 2008-525161).

However, the conventional examples, having structures such as described above, have problems such as the following.

Specifically, as illustrated in FIG. 23, in a scintillator block 53 the area of the surface that is in contact with the light guide 55 (hereinafter termed the “light-emitting face”) has essentially the same surface area as the face of the solid-state photodetector 57 that is in contact with the light guide 55 (hereinafter termed the “photodetecting face”). Because of this, the elements that structure the solid-state photodetector 57 must have wide photodetecting faces, in accordance with the area of the light-emitting faces.

However, manufacturing of a SiPM element or an APD element with a large surface area is extremely difficult, when compared to the relative ease of manufacturing a photoelectron tube with a large area. Because of this, when using a single SiPM element, or the like, in a solid-state photodetector, it is not possible to secure an adequately large photodetecting face, in accordance with the light-emitting face of the scintillator block.

The structure of a radiation detector 60, according to a conventional example, used for solving this problem will be explained using FIG. 24. The solid-state photodetector 61 that structures the radiation detector 60 is provided with a SiPM array 63 and a substrate portion 65. In the SiPM array 63, a plurality of SiPM elements 67 is arranged in a two-dimensional matrix. Each SiPM element 67 is provided with a photodetecting portion 69, where, in the photodetecting portion 69, the scintillator light is detected and converted into an electric signal. The substrate portion 65 is provided under the SiPM array 63, and performs processing of the electric signals that have been converted by the photodetecting portions 69, to output imaging information. A light guide 71 is disposed over the solid-state photodetector 61, where the scintillator block 73 is provided over the light guide 71. The solid-state photodetector 61 and the light guide 71 are optically coupled, as are the light guide 71 and the scintillator block 73.

That is, the SiPM array 63 is structured from a collection of a large number of SiPM elements 67 that have small photodetecting areas, and thus the solid-state photodetector 61 secures a photodetection area that is wide enough for the light-emitting face of the scintillator block 73 in the solid-state photodetector 61.

However, because the large number of SiPM elements 67 is arrayed two-dimensionally, there are gap portions 75 between the individual SiPM elements 67. Because of this, if an adhesive agent 77 that has low viscosity were used when optically coupling the light guide 71 and the solid-state photodetector 61, then, as illustrated in FIG. 25, the adhesive agent 77, due to its low viscosity, would penetrate into the interior of the substrate portion 65 through the gap portions 75. Given this, the low-viscosity adhesive agent 77 that has thus penetrated would interfere with the electrical conductivity of the substrate portion 65, thereby preventing the proper operation of the processing of the electric signals in the substrate portion 65. The result would be a dramatic drop in performance of the radiation detector 60.

Given this, typically a high-viscosity adhesive agent 79 is used as the adhesive agent for the optical coupling. In this case, as illustrated in FIG. 26, the high-viscosity adhesive agent 79 does not penetrate into the interior of the substrate portion 65, but now a new problem arises in the radiation detector 60. Specifically, air bubbles A occur in the interior of the high-viscosity adhesive agent 79 for coupling the solid-state photodetector 61 to the light guide 71. Because of this, the scintillator light L that is transmitted through the light guide 71 is scattered by the air bubbles A. When the scintillator light L is scattered, it becomes impossible to obtain precise information regarding the position at which the pair annihilation occurred, thus reducing the accuracy of the imaging information that is obtained from the radiation detector 60. Moreover, because the adhesive strength of the high-viscosity adhesive agent 79 is reduced by the air bubbles that are mixed in, the problem that the coupling between the solid-state photodetector 61 and the light guide 71 is reduced is also a concern.

Moreover, in the radiation detector 60 of the conventional example, as illustrated in FIG. 27, typically a reflecting mask 81 is provided over the SiPM element 67. The reason for this is that, in the SiPM element 67, the scintillator light that is incident on a photodetecting portion 69 is converted into an electric signal, while, in contrast, the scintillator light that is incident onto a part other than a photodetecting portion (hereinafter termed a non-sensitive portion”) is not converted into an electric signal.

As illustrated in FIG. 28, a plurality of opening portions 83 that is arranged in a two-dimensional matrix shape is provided in the reflecting mask 81, where the locations and sizes of the opening portions 83 are designed so as to be coincident with the individual photodetecting portions 69. That is, because the opening portions 83 are positioned over the respective photodetecting portions 69, the scintillator light that is directed toward a photodetecting portion 69 passes through the opening portion 83, to be incident on the photodetecting portion 69. On the other hand, scintillator light that is directed toward a non-sensitive portion is completely reflected by the reflecting mask 81, to ultimately be incident on the photodetecting portion 69. Consequently, this enables the scintillator light to be converted efficiently into electric signals.

However, in the structure illustrated in FIG. 27, many air bubbles A are produced within not only the high-viscosity adhesive agent 85 that couples the solid-state photodetector 61 to the reflecting mask 81, but also within the high-viscosity adhesive agent 87 that couples the reflecting mask 81 to the light guide 71. Because the scintillator light is scattered by the large number of air bubbles A that are produced, the accuracy of the imaging information that is obtained suffers. Moreover, because the opening portions 83 are air spaces within the radiation detector, the faces for bonding the reflecting mask 81 and the light guide 71, and the faces for bonding the solid-state photodetector 61 and the reflecting mask 81 are limited to narrow regions. The result is that the couplings between the solid-state photodetector 61, the reflecting mask 81, and the light guide 71 are extremely weak, so the problem of easy delamination is a concern.

When the radiation detectors use SiPM elements, or the like, as the photodetecting elements, it is envisioned that the radiation detector be used in a temperature range of between, for example, −20° C. and +25° C., in order to suppress noise that is produced within the photodetecting elements. That is, the radiation detector is to be used under conditions wherein there will be a tendency for the adhesive strengths between components to be reduced due to thermal expansion due to temperature differentials. Consequently, in a radiation detector that incorporates SiPM elements, that is, in a radiation detector that is used in a PET-MR, it is necessary to couple the components together extremely securely. However, it is extremely difficult to respond to the requirements set forth above in a radiation detector having the conventional structure.

The present inventive concept was created in contemplation of the situation described above, and the object thereof is to provide a radiation detector, and a radiation detector manufacturing method, having secure optical coupling even when SiPM elements are arranged in a two-dimensional matrix in a PET-MR.

### SUMMARY

In order to achieve the object set forth above, the present subject matter has the following structure: A radiation detector according to the present disclosure comprises: a scintillator block for detecting incident radiation and emitting light; a light guide, optically coupled to the scintillator block, for transmitting light emitted from the scintillator block; a solid-state photodetector, wherein a plurality of photodetecting elements for converting, into electric signals, light that is transmitted from the light guide, is arrayed in a two-dimensional matrix, and is optically coupled to the light guide; and a reflector for reflecting light, disposed between the light guide and the solid-state photodetector, and having opening portions in positions facing the photodetecting portions of the photodetecting elements. A first adhesive layer bonds the reflector and the solid-state photodetector. A first filling layer fills a gap portion between the photodetecting elements; a second adhesive layer bonds the light guide and the reflector; and a second filling layer fills an opening portion that is provided in the reflector.

Given the radiation detector according to the present disclosure, the plurality of photodetecting elements that structure the solid-state photodetector are arranged in a two-dimensional matrix shape. The first filling layer is provided in the gap portions between the individual photodetecting elements that are thus arranged. Typically, when it has not been possible to manufacture a single photodetecting element having a large photodetecting surface, the large photodetecting surface has been secured as a collection of photodetecting elements by arraying a plurality of photodetecting elements two-dimensionally. However, in the radiation detector according to the conventional example, when the photodetecting elements are arrayed two-dimensionally, then when bonding the solid-state detectors and the reflecting means together using an adhesive agent, there would be a tendency to have bubbles within the adhesive agent. The scintillator light would tend to be scattered by the bubbles that are present, making it impossible to obtain accurate information regarding the position at which pair annihilation has occurred. The result is a reduction in the accuracy of the imaging information that is obtained by the radiation detector.

On the other hand, in the radiation detector according to the present disclosure the gap portions are completely blocked by the first filling layer, making it is possible to avoid the incursion of air bubbles into the first adhesive layer through the gap portions. That is, in the first adhesive layer the scattering of scintillator light by air bubbles is prevented, making it possible to obtain high-quality imaging information by detecting the positions of occurrences of the pair annihilation accurately. Moreover, the prevention of the incursion of air bubbles makes it possible to avoid the reduction in adhesive strength in the first adhesive layer due to air bubbles. Consequently, it is possible to securely couple the solid-state photodetector and the reflecting means, even in a structure wherein the photodetecting elements are arrayed two-dimensionally.

Furthermore, in the radiation detector according to the present disclosure, a second filling layer is provided for filling the opening portions that are provided in the reflecting means. Typically, reflecting means for reflecting light are provided at positions wherein the non-sensitive portions of the photodetecting elements are covered, in order to detect the scintillator light efficiently. The reflecting means are provided with a plurality of opening portions that are arranged in a two-dimensional matrix. Given this, when the reflecting means are disposed over the solid-state photodetector, the individual opening portions are designed so as to be disposed over the individual photodetecting portions. Because of this, the scintillator light that is directed toward the photodetecting portion passes through the opening portion to be incident on the photodetecting portion. The scintillator light that is directed to a non-sensitive portion is reflected to be incident again on the photodetecting portion. In other words, the scintillator light is caused to be incident on the photodetecting portions more efficiently, to be converted into electric signals, and thus the electric signals that are outputted by the radiation detector are larger.

However, when reflecting means are provided in the radiation detector according to the conventional example, when the reflecting means and the light guide are bonded by an adhesive agent, more air bubbles will be included in the adhesive agent. In this case, there will be a greater tendency for the scintillator light to be scattered by the air bubbles, which reduces the accuracy of the imaging information that is obtained by the radiation detector. Moreover, because the opening portions are air spaces within the radiation detector, in the opening portions the light guide and the reflecting means, and the reflecting means and the solid-state photodetector, cannot be bonded at the opening portions. In other words, the reflecting means could only be bonded to the light guide and to the solid-state photodetector in a limited range that excludes the opening portions, so that the adhesive strengths between the light guide, the reflecting means, and the solid-state photodetector have been extremely weak. The result was that, in the radiation detector, the problem of the ease with which delamination of the light guide, the reflecting means, and the solid-state photodetector occurs in the radiation detector has been a concern.

On the other hand, in a radiation detector according to the present embodiment, the second filling layer completely fills the opening portions that are provided in the reflecting means, thus making it possible to avoid the inclusion of air bubbles in the second adhesive layer from the opening portions. Because of this, the occurrence of air bubbles in the second adhesive layer can be prevented, so that there will be no scattering of the scintillator light by the air bubbles. Moreover, the adhesive agent that forms the second filling layer adheres to the light guide through the second adhesive layer, and adheres to the solid-state photodetector through the first adhesive layer. That is, the surface for adhesion between the reflecting means and the light guide, and the surface for adhesion between the reflecting means and the solid-state photodetector, are larger by an amount equal to the second filling layer. The first adhesive layer, the first filling layer, the second adhesive layer, and the second filling layer are structured from a high-viscosity adhesive agent that is used as the optical coupler. Consequently, the light guide, the reflecting means, and the solid-state photodetector are coupled optically and securely. The result is that it is possible to achieve a radiation detector that has both high scintillator light conversion efficiency and secure optical coupling.

Preferably the radiation detector set forth above further comprises: an adhesive layer coated portion, structured from an adhesive agent used for optical coupling, coating, in tight contact, a side peripheral portion of the first adhesive layer and a side peripheral portion of the second adhesive layer; and a reflecting material for reflecting light, coating, in tight contact, the scintillator block, the light guide, the solid-state photodetector, and the adhesive layer coated portion.

Given the structure set forth above, the radiation detector is provided with an adhesive layer coated portion and reflecting materials. Given this, the adhesive layer coated portion makes it possible to prevent the incursion of air bubbles or moisture from the outside into the first adhesive layer and the second adhesive layer. That is, the reduction in adhesive strength in the first adhesive layer and the second adhesive layer is prevented, making it possible to reliably prevent delamination of the light guide and the reflecting means, and of the reflecting means and the solid-state photodetector. Moreover, the adhesive layer coated portion is structured from an adhesive agent, and thus the couplings between the light guide and the reflecting means, and between the reflecting means and the solid-state photodetector, are made more secure by the adhesive strength of the adhesive layer coated portion itself. Consequently, this makes it possible to achieve a radiation detector wherein there is no delamination of the components from each other, even under conditions wherein there would be a tendency for the adhesive strength to be reduced.

Moreover, because the outer peripheral portion of the radiation detector is coated by a reflecting material, the scintillator light that is directed toward the outside of the radiation detector is reflected back toward the interior of the radiation detector by the reflecting material. The scintillator light that is reflected to the interior is detected by the photodetecting portions, to be converted into electric signals. That is, the scintillator light is prevented from exiting to the outside of the radiation detector, thereby enabling the scintillator light to be converted efficiently into electric signals. The result is that the electric signals that are outputted from the radiation detector are larger.

Moreover, preferably the radiation detector set forth above further comprises: a reflecting material for reflecting light, coating, in tight contact, a side peripheral portion and a top face portion of the scintillator block and a side peripheral portion of the light guide.

In the structure set forth above, a scintillator compound unit is formed wherein the scintillator block and the light guide are coupled optically in advance and the side peripheral portion and the top face portion of the scintillator compound unit is coated with a reflecting material that reflects light. That is, the reflecting material is in a state that is in tight contact with the scintillator compound unit, thus making it possible to prevent reliably the scintillator light from exiting to the outside of the radiation detector. Consequently, this enables the scintillator light to be converted into electric signals more efficiently.

Moreover, preferably the radiation detector set forth above further comprises: an adhesive layer coated portion, structured from an adhesive agent used for optical coupling, coating, in tight contact, respective side peripheral portions of the first adhesive layer, the second adhesive layer, and the reflecting material.

In the structure set forth above, the adhesive layer coated portion makes it possible to prevent the incursion of air bubbles and moisture from the outside into the first adhesive layer and the second adhesive layer. That is, the reduction in adhesive strength in the first adhesive layer and the second adhesive layer is prevented, making it possible to prevent reliably delamination of the light guide and the reflecting means, and of the reflecting means and the solid-state photodetector. Consequently, this makes it possible to achieve a radiation detector wherein there is no delamination of the components from each other, even under conditions where there would be a tendency for the adhesive strength to be reduced.

Moreover, preferably the radiation detector set forth above further comprises: an adhesion strengthening material, coating, in tight contact, a side peripheral portion of the reflecting material, adhered to the adhesive agent used for optical coupling.

Given the structure set forth above, an adhesion strengthening material is provided on the side peripheral portion of the reflecting material. The adhesion strengthening material is bonded securely to the adhesive agent that is used in the optical coupling, and thus the reflecting material and the adhesive layer coated portion are bonded more securely through the adhesion strengthening material. Consequently, this can further increase the secureness of the optical coupling in the radiation detector.

Moreover, preferably, in the radiation detector set forth above: the reflecting material is a material that bonds to the adhesive agent that is used for optical coupling.

Because, in the structure described above, the reflecting material itself has the property of adhering securely to the adhesive agent that is used for the optical coupling, the reflecting material and the adhesive layer coated portion are directly and more tightly bonded together. Consequently, the strengths of the optical couplings in the radiation detector are even more secure.

Moreover, preferably, in the radiation detector set forth above: the photodetecting element is a SiPM element or an APD element.

Given the structure set forth above, SiPM elements or APD elements are used for the photodetecting elements that structure the radiation detector. These elements are not affected by the magnetic fields that are produced by the MR device, and thus the radiation detector according to the present disclosure can be used in a PET-MR. That is, it is possible to achieve a PET-MR having a radiation detector wherein not only is the scintillator light converted more efficiently into electric signals, but the optical couplings between components are also made more secure.

There is also provided a manufacturing method a radiation detector. Specifically, there are, included: a gap filling step for filling, with an adhesive agent that is used for optical coupling, a gap portion that is provided between photodetecting elements that structure a solid-state photodetector. An adhesive agent removing step removes an adhesive agent that remains on the surface of the solid-state photodetector after the gap portion filling step. A reflecting mask placing step places, onto a surface of the solid-state photodetector, a reflecting mask that is provided with an opening portion in a position facing a photodetecting portion of a photodetecting element, performed after the adhesive agent removing step. An opening portion filling step, after the reflecting mask placing step, fills an opening portion, provided in the reflecting mask, with an adhesive agent used for optical coupling, and also for coupling the solid-state photodetector and the reflecting mask. A light guide coupling step, performed after the opening portion filling step, couples the light guide and the reflecting mask. Ascintillator coupling step, performed after the light guide coupling step, optically couples the scintillator block and the light guide.

In the radiation detector according to the present disclosure, the photodetecting elements in the solid-state photodetector are arranged in a two-dimensional matrix shape, and the gap portions between the photodetecting elements that are thus arranged are filled by the adhesive agent that is used for the optical coupling, in the gap portion filling step. After the gap portion filling step, the gap portions are completely covered, making it possible to prevent the inclusion of air bubbles from the gap portions into the adhesive agent. That is, this arrangement prevents the scattering of the scintillator light by the air bubbles, thus making it possible to obtain an image signal with high accuracy by accurately detecting the locations where pair annihilation occurs. Because of this, it is possible to achieve a radiation detector that is able to produce highly accurate imaging information, even when using solid-state photodetectors that are structured from photodetecting elements that are arranged in two-dimensional matrices.

In the adhesive agent removing step, the adhesive agent that remains on the surfaces of the photodetecting elements that structure the solid-state photodetector in the gap portion filling step is removed, thus causing the surface of the photodetecting elements to be in a smooth state. Consequently, the reflecting mask is provided in a more stable state on the surface of the photodetecting elements in the reflecting mask placing step.

In the reflecting mask placing step, a reflecting mask is placed on the surface of the photodetecting elements that have been made level in the adhesive agent removing step. The opening portions that are provided in the reflecting mask are designed so as to be coincident with the photodetecting portions that are provided in the photodetecting elements, and thus the opening portions are positioned directly over the photodetecting portions in the reflecting mask placing step. Moreover, those parts other than the photodetecting portions in the photodetecting elements, that is, the non-sensitive portions, are covered by the reflecting mask. Consequently, the scintillator light that is directed toward a photodetecting portion is incident onto the photodetecting portion through an opening portion, and the scintillator light that is directed toward a non-sensitive portion is reflected by the reflecting mask to ultimately be incident on a photodetecting portion. In other words, the scintillator light is caused to be incident on the photodetecting portions more efficiently, to be converted into electric signals, and thus the electric signals that are outputted by the radiation detector are larger.

In the opening portion filling step, the opening portion is filled with the adhesive agent that is used in the optical coupling. After the opening portion filling step, the opening portions are completely filled with the adhesive agent, thus making it possible to avoid the inclusion of air bubbles, from the opening portions, within the adhesive agent that bonds the reflecting mask and the light guide. That is, because the scattering of the scintillator light by air bubbles is prevented, it is possible to obtain imaging information with high accuracy by detecting accurately the locations wherein pair annihilation occurs, in a radiation detector that has a structure that is provided with the reflecting mask.

Moreover, because the opening portions are filled with the adhesive agent that is used for the optical coupling, the surfaces for bonding the reflecting mask and the light guiding, and the surfaces for bonding the reflecting mask and the solid-state photodetector, are larger. Moreover, the reflecting mask, the light guide, and the solid-state photodetector are bonded by a high viscosity adhesive agent that is used in optical coupling. Because of this, the light guide, the reflecting mask, and the solid-state photodetector are coupled optically and securely.

In the light guide coupling step, the light guide is coupled optically to the reflecting mask while there are visual inspections from above whether or not there are bubbles included. This makes it possible to avoid more reliably the inclusion of air bubbles in the adhesive agent that couples the light guide to the reflecting mask.

The scintillator block and the light guide are optically coupled in the scintillator coupling step. The result is that the scintillator light is transmitted to the solid-state photodetector by the light guide more efficiently, to be converted to electric signals, thus causing the electric signals that are outputted from the radiation detector to be larger.

As described above, through the radiation detector manufacturing method according to the present disclosure, the light guide, the reflecting mask, and the solid-state detector are more securely coupled in a radiation detector that is provided with photodetecting elements that are disposed two-dimensionally and reflecting means that have opening portions. That is, this makes it possible to achieve a radiation detector having a high scintillator light conversion efficiency and secure optical coupling.

Moreover, preferably the radiation detector manufacturing method set forth above further includes: a reflecting material coating step, performed after the scintillator coupling step, which leaves at least a portion of an adhesive agent that is forced out to the side peripheral portions of the light guide, the reflecting mask, and the solid-state photodetector, and coating, with a reflecting material that reflects light, the respective side peripheral portions of the scintillator block, the light guide, the solid-state photodetector, and the remaining adhesive agent.

Given the structure set forth above, in the light guide coupling step and the scintillator coupling step, a portion of the adhesive agent by which the light guide, the reflecting means, and the solid-state photodetector are bonded will be forced out to the side peripheral portion of the radiation detector. In the reflecting material coating step, the adhesive agent will remain in an amount that covers, from the side peripheral portion, at least the bonding surface between the light guide and the reflecting means and the bonding surface between the reflecting means and the solid-state photodetector. Given this, the side peripheral portion and the top face portion of the scintillator block, the side peripheral portion of the light guide, the side peripheral portion of the solid-state photodetector, and the adhesive agent are coated with a reflecting material that reflects light.

The adhesive agent that remains on the side peripheral portion of the radiation detector prevents the incursion of air and moisture, or the like, from the outside into the bonding surface between the light guide and the reflecting means and into the bonding surface between the reflecting means and the solid-state photodetector. Because of this, it is possible to avoid, more reliably, delamination of the light guide from the reflecting means and of the reflecting means from the solid-state photodetector. Moreover, because the outer peripheral portion of the radiation detector is coated by a reflecting material, the scintillator light that is directed toward the outside of the radiation detector is reflected back toward the interior of the radiation detector by the reflecting material. The scintillator light that is reflected to the interior is detected by the photodetecting portions, to be converted into electric signals. Consequently, this makes it possible to prevent the scintillator light from leaking out to the outside of the radiation detector, thus enabling the scintillator light to be converted efficiently into electric signals.

Furthermore, having remaining adhesive agent on the side peripheral portion, instead of removing it, can prevent the incursion of air, moisture, or the like, into the adhesive agent layers for bonding the light guide and the reflecting means and the reflecting means and the solid-state photodetector. Because of this, it is possible to avoid, any reduction in the strength of adhesion between the light guide and the reflecting means, or between the reflecting means and the solid-state photodetector, caused by inclusion of air or moisture. Moreover, the couplings between the light guide and the reflecting means, and between the reflecting means and the solid-state photodetector, are made more secure by the adhesive agent itself, that remains on the side peripheral portions. Consequently, this makes it possible to achieve a radiation detector wherein there is no delamination of the light guide, the reflecting means, and the solid-state photodetector from each other, even under conditions wherein there would be a tendency for the adhesive strength to be reduced.

Moreover, preferably the radiation detector manufacturing method set forth above further includes, instead of the light guide coupling step and the scintillator coupling step: a compound unit forming step for optically coupling the scintillator block and the light guide to form a scintillator compound unit wherein the side peripheral portion and the top face portion of the scintillator block and the side peripheral portion of the light guide are coated with a reflecting material of that reflects light; and a compound unit coupling step, after the opening portion filling step and the compound unit forming step, for coupling the scintillator compound unit and the reflecting mask.

Given the structure set forth above, a scintillator compound unit is formed wherein the scintillator block and the light guide are optically coupled through the compound unit forming step. Given this, the side peripheral portion and top face portion of the scintillator compound unit that is formed is covered in tight contact with a reflecting material that reflects light. Consequently, the scintillator light that is directed outside of the radiation detector is reflected more reliably to the interior of the radiation detector by the reflecting material to ultimately be converted into an electric signal by the photodetecting element. That is, this makes it possible to more reliably avoid the scintillator light from leaking out to the outside of the radiation detector, thus enabling the scintillator light to be converted more efficiently into electric signals.

Moreover, preferably in the radiation detector manufacturing method set forth above: at least a portion of the adhesive agent that is forced out to the respective side peripheral portions of the scintillator compound unit, the reflecting mask, and the solid-state photodetector is left remaining.

Given the structure set forth above, having the adhesive agent remaining on the side peripheral portion, instead of removing it, prevents the incursion of air, moisture, or the like, from the outside into the adhesive agent layers for bonding the light guide and the reflecting means and the reflecting means and the solid-state photodetector. Because of this, it is possible to prevent, more reliably, delamination of the light guide from the reflecting means and of the reflecting means from the solid-state photodetector. Moreover, the couplings between the light guide and the reflecting means, and between the reflecting means and the solid-state photodetector, are made more secure by the adhesive agent itself that remains on the side peripheral portions. Consequently, this makes it possible to achieve a radiation detector wherein there is no delamination of the light guide, the reflecting means, and the solid-state photodetector from each other, even under conditions wherein there would be a tendency for the adhesive strength to be reduced.

Moreover, preferably the radiation detector manufacturing method set forth above further includes: a material that is adhered to the adhesive agent that is used for optical coupling, on a side peripheral portion of the scintillator compound unit.

Because, in the structure described above, a material that adheres securely to the adhesive agent is provided on the side peripheral portion of the reflecting material, the adhesive agent that remains on the side peripheral portion, without being removed, is bonded more securely to the reflecting material. Consequently, this can further increase the secureness of the optical coupling in the radiation detector.

Moreover, preferably, in the radiation detector manufacturing method set forth above: the reflecting material is a material that bonds to the adhesive agent that is used for optical coupling.

Because, in the structure described above, the reflecting material itself adheres securely to the adhesive agent that is used for the optical coupling, the adhesive agent that remains on the side peripheral portion, without being removed, is bonded more directly and more securely to the reflecting material. Consequently, the strengths of the optical couplings in the radiation detector are even more secure.

Moreover, preferably, in the radiation detector manufacturing method set forth above: the photodetecting element is a SiPM element or an APD element.

Given the structure set forth above, SiPM elements or APD elements are used for the photodetecting elements that structure the radiation detector. These elements are not affected by the magnetic fields that are produced by the MR device, and thus the radiation detector according to the present disclosure can be used in a PET-MR. That is, it is possible to achieve a PET-MR having a radiation detector wherein not only is the scintillator light converted more efficiently into electric signals, but the optical couplings between components are also made more secure.

With the radiation detector and the radiation detector manufacturing method according to the present disclosure, the gap portions between the photodetecting elements that are arrayed two-dimensionally and the opening portions that are provided in the reflecting means are filled with a high-viscosity adhesive agent. The result thereof is the ability to prevent the inclusion of air bubbles in the adhesive agent that forms adhesive layers. That is, there is no scattering, by air bubbles, of the scintillator light that is incident into the photodetecting portions, thus making it possible to obtain more accurate imaging information. Moreover, the reduction in adhesive strength between the solid-state photodetector, the reflecting mask, and the light guide due to the inclusion of air bubbles is avoided. Because of this, in a radiation detector that uses SiPM elements as photodetecting elements that must be arrayed two-dimensionally, the solid-state photodetector, the reflecting mask, and the light guide are coupled optically and securely. Because a SiPM element is not affected by the strong magnetic fields that are produced by the MR device, the radiation detector according to the present disclosure can be used in a PET-MR. That is, it is possible to achieve a PET-MR having a radiation detector where not only is the scintillator light converted more efficiently into electric signals, but the optical couplings between components are also made more secure.

Moreover, as described above, when the radiation detectors use SiPM elements, or the like, as the photodetecting elements, it is envisioned that the radiation detector be used in a temperature range of between, for example, −20° C. and 25°, in order to suppress noise that is produced within the photodetecting elements. That is, the radiation detector is to be used under conditions wherein there will be a tendency for the adhesive strengths between components to be reduced due to the effect of thermal expansion due to temperature differentials. That is, the radiation detector according to the present disclosure has extremely secure optical coupling, thus enabling use even under conditions wherein there would be a tendency for the adhesive strength between the components to be reduced. This makes it possible to achieve a PET-MR where less noise is produced, through using the PET-MR under conditions where there is a large temperature difference.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTIONS OF THE DRAWINGS

The drawing figures depict one or more implementations in accord with the present teachings, by way of example only, not by way of limitation. In the figures, like reference numerals refer to the same or similar elements.

FIG. 1 is a vertical sectional drawing illustrating the schematic structure of a radiation detector according to a first embodiment;

FIG. 2 is a perspective diagram illustrating the schematic structure of a reflecting mask according to the first embodiment;

FIG. 3 is a flowchart illustrating the steps in a radiation detector manufacturing method according to the first embodiment;

FIG. 4 is a vertical sectional diagram illustrating the schematic structure of a solid-state photodetector according to the first embodiment;

FIG. 5 is a vertical sectional diagram illustrating a schematic structure of the radiation detector in the gap portion filling step according to the first embodiment;

FIG. 6 is a vertical sectional diagram illustrating a schematic structure of the radiation detector in the adhesive agent removing step according to the first embodiment;

FIG. 7 is a vertical sectional diagram illustrating a schematic structure of the radiation detector in the reflecting mask placing step according to the first embodiment;

FIG. 8 is a vertical sectional diagram illustrating a schematic structure of the radiation detector in the opening portion filling step according to the first embodiment;

FIG. 9 is a vertical sectional diagram illustrating a schematic structure of the radiation detector in the opening portion filling step according to the first embodiment;

FIG. 10 is a vertical sectional diagram illustrating a schematic structure of the radiation detector in the scintillator coupling step according to the first embodiment;

FIG. 11 is a vertical sectional diagram illustrating a schematic structure of a radiation detector as set forth in the first embodiment wherein the adhesive layer coated portion is formed after the scintillator coupling step;

FIG. 12 is a vertical sectional diagram illustrating a schematic structure of the radiation detector in the reflecting material coating step according to the first embodiment;

FIG. 13 is a vertical sectional drawing illustrating the schematic structure of a radiation detector according to a second embodiment;

FIG. 14 is a flowchart illustrating the steps in a radiation detector manufacturing method according to the second embodiment;

FIG. 15 is a vertical sectional diagram illustrating a schematic structure of the compound scintillator unit in the compound unit forming step according to the second embodiment;

FIG. 16 is a vertical sectional diagram illustrating a schematic structure of the radiation detector in the compound unit coupling step according to the second embodiment;

FIG. 17 is a vertical sectional diagram illustrating a schematic structure of a radiation detector as set forth in the second embodiment wherein the adhesive layer coated portion is formed after the compound unit coupling step;

FIG. 18 is a vertical sectional diagram illustrating the behavior of the scintillator light in the radiation detector according to the first embodiment;

FIG. 19 is a vertical sectional diagram illustrating the behavior of the scintillator light in the radiation detector according to the second embodiment;

FIG. 20 is a vertical sectional diagram illustrating the schematic structure of a scintillator compound unit provided with a viscous material, in a modified example according to the second embodiment;

FIG. 21 is a vertical sectional diagram illustrating the schematic structure of a radiation detector provided with a viscous material, in a modified example according to the second embodiment;

FIG. 22 is a vertical sectional diagram illustrating the schematic structure of a typical PET device;

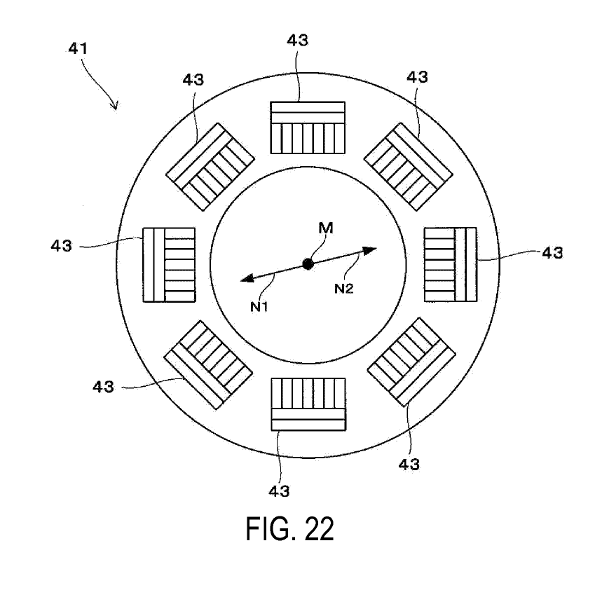

FIG. 23 is a perspective diagram illustrating the schematic structure of a typical radiation detector;

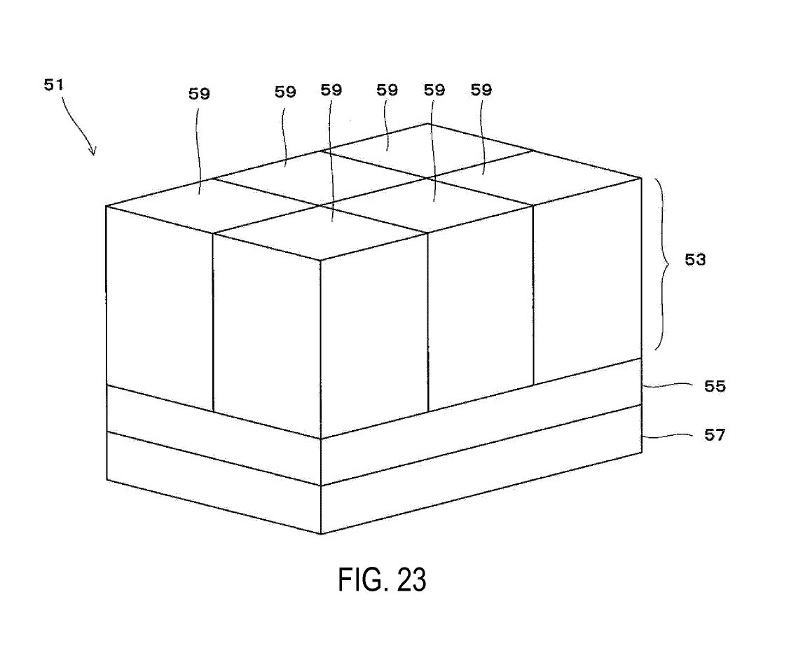

FIG. 24 is a vertical sectional drawing illustrating the schematic structure of a radiation detector according to a conventional example;

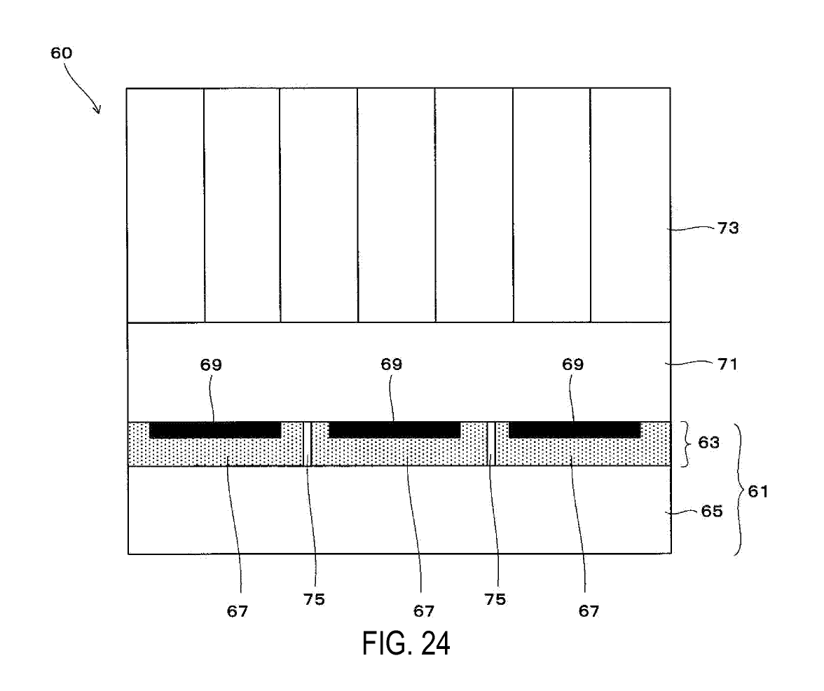

FIG. 25 is a vertical sectional diagram illustrating schematically a case wherein a low-viscosity adhesive agent is used in a radiation detector manufacturing method according to a conventional example;

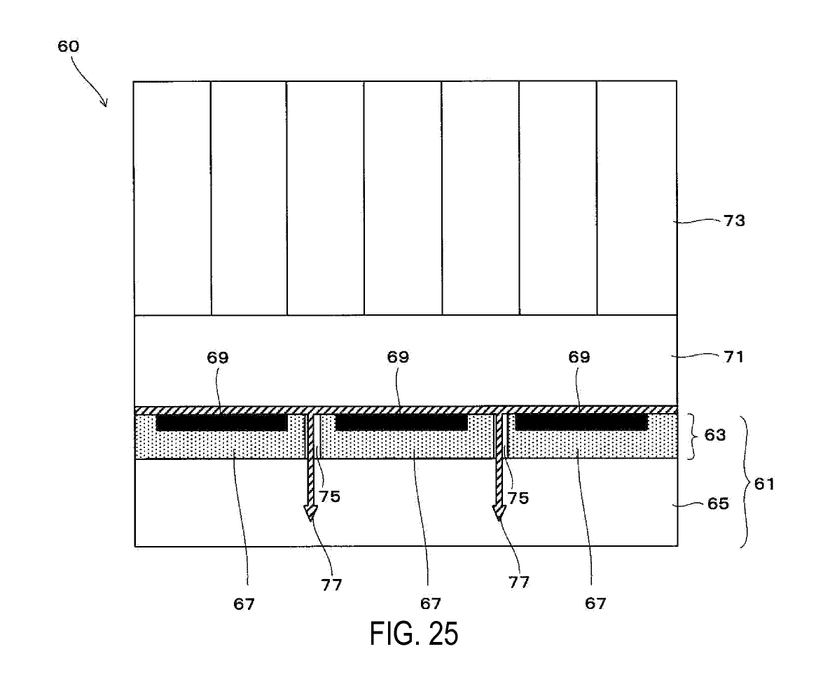

FIG. 26 is a vertical sectional diagram illustrating schematically a case wherein a high-viscosity adhesive agent is used in a radiation detector manufacturing method according to a conventional example;

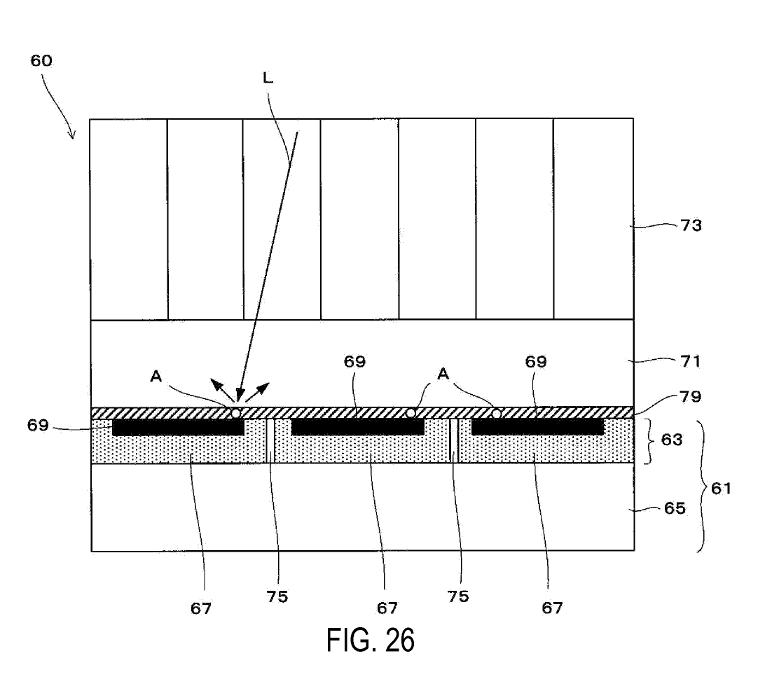

FIG. 27 is a vertical sectional diagram illustrating schematically a case wherein a high-viscosity adhesive agent is used in a radiation detector manufacturing method according to a conventional example wherein a reflecting mask is provided; and

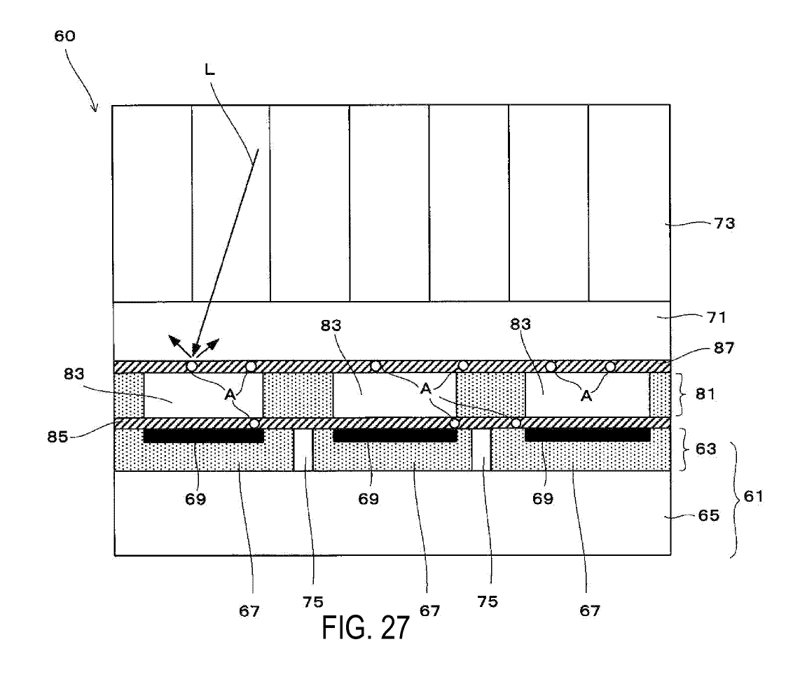

FIG. 28 is a perspective diagram illustrating the schematic structure of a reflecting mask according to a conventional example.

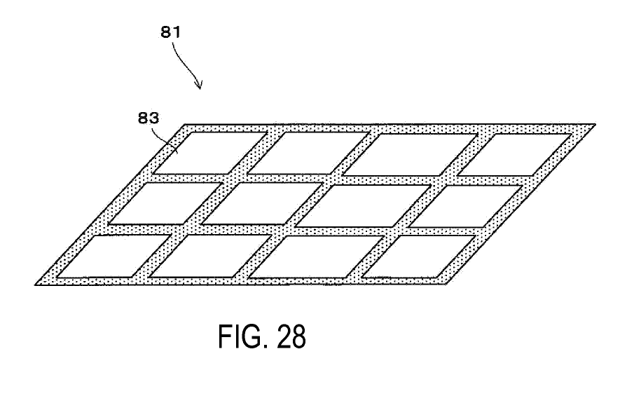

### DETAILED DESCRIPTION

### Embodiment 1

### Explanation of the Overall Structure

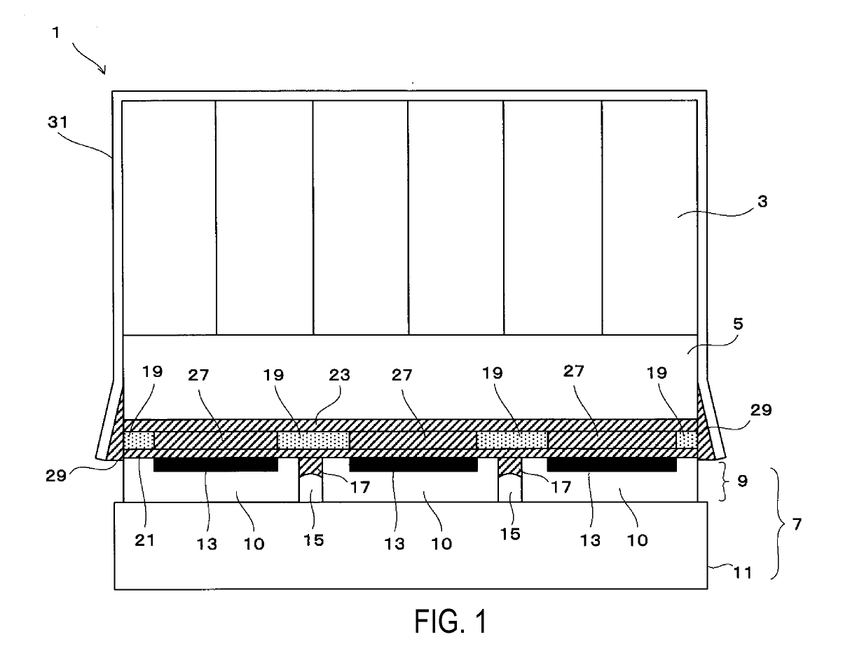

As illustrated in FIG. 1, the radiation detector 1 according to a first embodiment has a structure wherein a scintillator block 3, a light guide 5, and a solid-state photodetector 7 are layered, from the top down, in the sequence set forth above. The scintillator block 3 absorbs γ rays emitted from the subject body and emits light. The light guide 5 is coupled optically, through a high-viscosity adhesive agent, to the scintillator block 3, and transmits the light emitted from the scintillator block 3 to the solid-state photodetector 7. The solid-state photodetector 7 is provided with a photodetecting element array 9 and a substrate portion 11.

The photodetecting element array 9 has a structure wherein a plurality of photodetecting elements 10 is arranged in the form of a two-dimensional matrix. A photodetecting portion 13 is provided on the surface of the photodetecting element 10 on the light guide 5 side. In the photodetecting portion 13, the light that is transmitted by the light guide 5 is detected and converted into an electric signal. A SiPM element is used as the photodetecting element 10. The substrate portion 11 is provided under the photodetecting element array 9, and performs processing of the electric signals converted by the photodetecting portions 13. Gap portions 15 with widths of about 0.2 mm are provided between the individual photodetecting elements 10, where the upper layer of the gap portions 15 is filled by a gap portion filling layer 17. Note that the gap portion filling layer 17 corresponds to the first filling layer in the present disclosure.

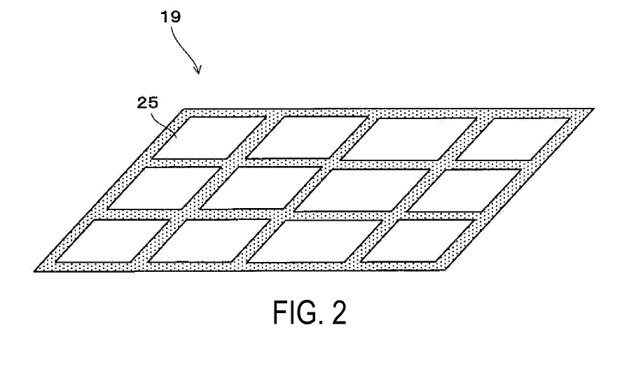

A reflecting mask 19, a first adhesive layer 21, and a second adhesive layer 23 are provided between the light guide 5 and the solid-state photodetector 7. The reflecting mask 19 is structured from a material that reflects light, such as the ESR Film™ (Enhanced Specular Reflective Film) manufactured by 3M Company. The reflecting mask 19 is bonded to the solid-state photodetector 7 by the first adhesive layer 21, and bonded to the light guide 5 through the second adhesive layer 23. Moreover, as illustrated in FIG. 2, a plurality of opening portions 25, arranged in the form of a two-dimensional matrix, is provided in the reflecting mask 19. The positions and sizes of the individual opening portions 25 are designed so as to match the positions and sizes of the individual photodetecting portions 13. That is, in FIG. 1 the opening portions 25 are positioned over the individual photodetecting portions 13. Additionally, the opening portions 25 are filled by an opening portion filling layer 27. Note that the reflecting mask 19 corresponds to the reflecting means in the present disclosure, and the opening portion filling layer 27 corresponds to the second filling layered in the present disclosure.

An adhesive layer coated portion 29 is provided on the respective side peripheral portions of the light guide 5, the solid-state photodetector 7, and the reflecting mask 19. The adhesive layer coated portion 29 strengthens the bond between the light guide 5 and the reflecting mask 19 and the bond between the solid-state photodetector 7 and the reflecting mask 19. The side peripheral portion and the top face portion of the scintillator block 3, the side peripheral portion of the light guide 5, and the side peripheral portion of the adhesive layer coated portion 29 are coated by a reflecting material 31. The reflecting material 31 is structured from a material that reflects light, such as a fluorine resin, and reflects into the radiation detector 1 light that is emitted from the scintillator block 3 and is directed to outside of the radiation detector 1.

Note that the gap portion filling layer 17, the first adhesive layer 21, the second adhesive layer 23, the opening portion filling layer 27, and the adhesive layer coated portion 29, that is, the parts in FIG. 1 that are indicated by the diagonal lines, are structured from a high-viscosity adhesive agent. For the high-viscosity adhesive agent, a high-viscosity adhesive agent of a silicone type that is used for optical coupling, such as RTV (Room Temperature Vulcanizing) rubber (KE-42, from Shin-Etsu Chemical Co., Ltd.) is used. That is, the light guide 5 and the photodetecting portion 13 are optically coupled through the first adhesive layer 21, the second adhesive layer 23, and the opening portion filling layer 27. Consequently, the scintillator light that is transmitted through the light guide 5 is incident onto the photodetecting portion 13, and converted into an electric signal, efficiently.

The reasons for using a silicone high-viscosity adhesive agent, using RTV rubber as an example, in the present disclosure are discussed below.

Firstly, a silicone high-viscosity adhesive agent has extremely high viscosity, and thus when filling the gap portions 15 that have widths of about 0.2 mm, it hardens in a form wherein it is stopped in the top layer of the gap portions 15. Because of this, the adhesive agent does not penetrate through the gap portions 15 to the substrate portion 11. Consequently, this makes it possible to avoid the occurrence of electrical connection failures on the substrate portion 11 caused by the adhesive agent.

Secondly, the silicone high-viscosity adhesive agent is able to cure at room temperature. Because the ability of the photodetecting elements used in the radiation detector to withstand heat is not high, the ambient temperature when the detector is used is limited. For example, the SiPM element must be used at a temperature of no more than 60° C., and a radiation detector 1 that incorporates the SiPM element must be manufactured or used at no more than 60° C. Because of this, a silicone low-viscosity adhesive agent, or the like, wherein the curing temperature is 80° C. or higher is not suitable for manufacturing the radiation detector 1. Consequently, a room temperature-curable silicone high-viscosity adhesive agent is an adhesive agent that is well suited for the manufacturing of a radiation detector 1 that uses a SiPM element.

Thirdly, a silicone high-viscosity adhesive agent is soft when compared to an epoxy adhesive agent. Because of this, if, during the manufacturing process for the radiation detector, an error is made when bonding components together, it is possible to separate the components that have been bonded incorrectly, without damaging the radiation detector, enabling bonding to be performed again. Consequently, this makes it possible to avoid more suitably errors in components and manufacturing of defective products in the manufacturing process.

### <Explanations of the Steps>

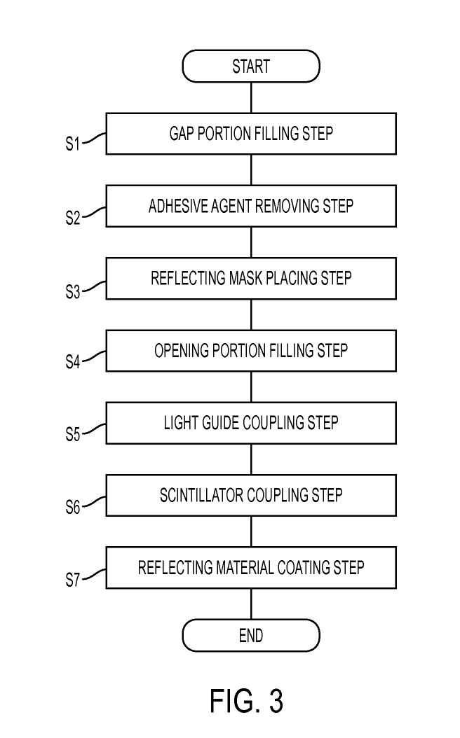

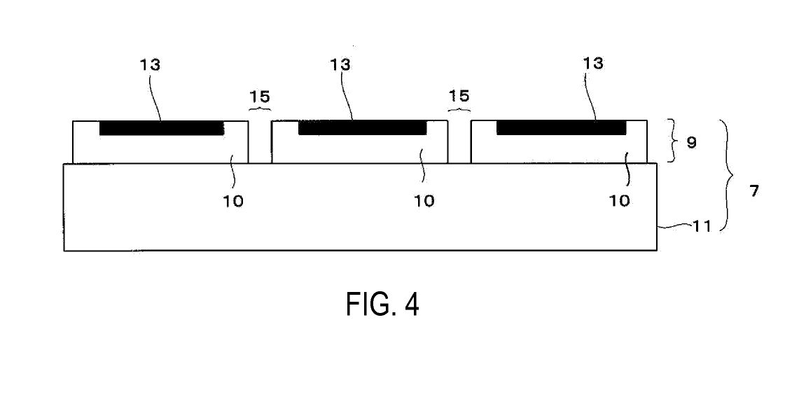

All of the steps in the method for manufacturing a radiation detector 1, structured as described above, will be explained next using FIG. 3 through FIG. 12. FIG. 3 is a flowchart for explaining the steps in the radiation detector manufacturing method according to a first embodiment, and FIG. 4 through FIG. 12 are vertical sectional diagrams illustrating schematic structures of the radiation detector according to the first embodiment in the individual manufacturing steps.

First, a solid-state photodetector 7 is prepared as illustrated in FIG. 4. As described above, the photodetecting element array 9 structures the solid-state photodetector 7 has a structure wherein a plurality of photodetecting elements 10 that is structured from SiPMs, is arranged in the form of a two-dimensional matrix. Because with a SiPM it is extremely difficult to manufacture a large surface area with a single unit, photodetecting elements 10 with small surface areas are combined into an array to form a photodetecting element array 9 having a large surface area. Because of this, gap portions 15 are formed between the individual photodetecting elements 10.

<Step S1 (Gap Portion Filling Step)>

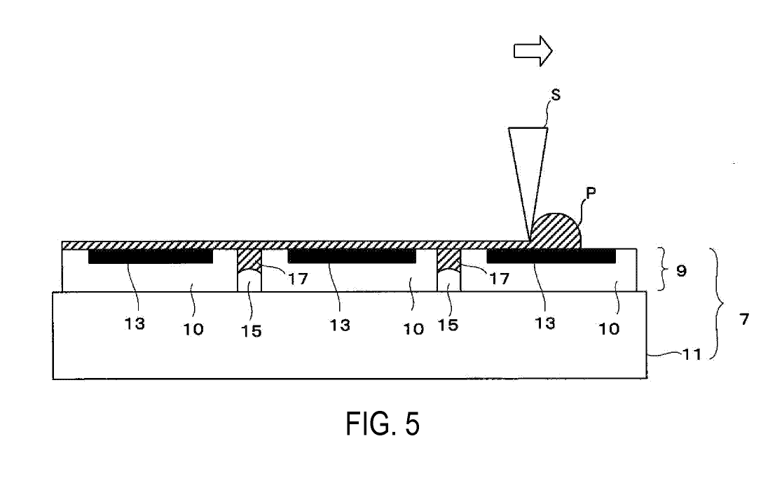

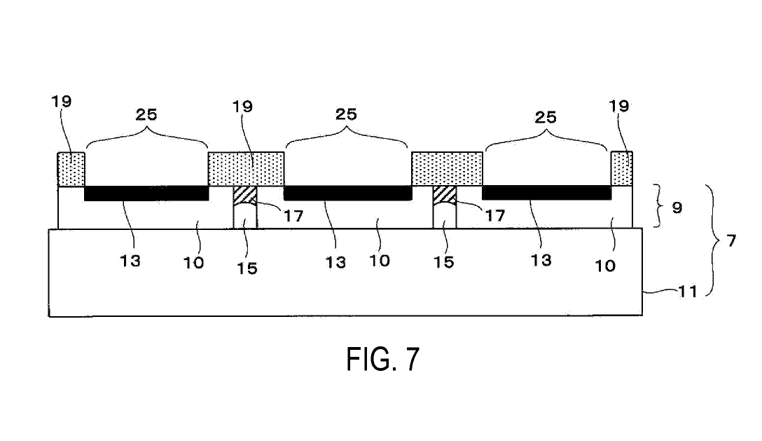

As illustrated in FIG. 5, a high-viscosity adhesive agent P and a squeegee S are used to fill the gap portions 15 in the solid-state photodetector 7. The arrow shown in FIG. 7 is the direction of movement of the squeegee S. The high-viscosity adhesive agent P is, for example, an RTV rubber, and the fluidity thereof is extremely low. Because of this, the high-viscosity adhesive agent P that fills the gap portions 15 forms a gap portion filling layer 17 that stops at the top layer of the gap portions 15, and the high-viscosity adhesive agent P does not penetrate through the gap portions 15 into the interior of the substrate portion 11. Consequently, there will be no electrical connection defects caused by the high-viscosity adhesive agent P in the substrate portion 11. The gap portion filling step is completed by forming the gap portion filling layer 17 in all of the gap portions 15 that are provided in the photodetecting element array 9.

<Step S2 (Adhesive Agent Removing Step)>

When the gap portion filling step has been completed, the high-viscosity adhesive agent P covers not just the gap portions 15, but also the surface of the photodetecting element array 9, in a state wherein there are recessed portions and raised portions produced on the surface of the solid-state photodetector 7. If the reflecting mask were to be adhered onto the solid-state photodetector 7 in a state wherein there are recessed and raised portions, the bonding surface would be unstable due to the recessed and raised portions, causing the adhesive strength between the solid-state photodetector 7 and the reflecting mask to be weak. The result would be a high likelihood of delamination of the solid-state photodetector 7 from the reflecting mask later, which would remarkably reduce the reliability of the radiation detector 1.

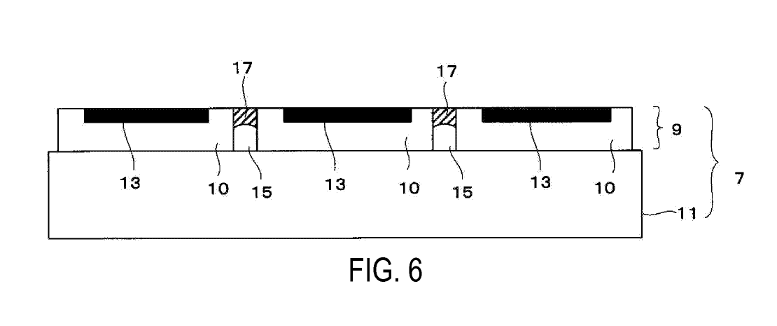

Because of this, as illustrated in FIG. 6, prior to the commencement of curing of the high-viscosity adhesive agent, only the high-viscosity adhesive agent that covers the surface of the photodetecting element array 9 is removed, using a solvent, to planarize the surface of the solid-state photodetector 7. The high-viscosity adhesive agent that forms the gap portion filling layer 17 is not removed by the adhesive agent removing step, and is cured quickly. Consequently, the top layer of the gap portions 15 is filled completely by the gap portion filling layer 17.

<Step S3 (Reflecting Mask Placing Step)>

After the adhesive agent removing step has been completed, then, as illustrated in FIG. 7, an adhesive material, such as double-sided tape, or the like, is used to apply the reflecting mask 19 onto the surface of the planarized solid-state photodetector 7. As illustrated in FIG. 2, a plurality of opening portions 25 is provided in the reflecting mask 19, where the positions of the individual opening portions 25 are designed so as to be coincident with the individual photodetecting portions 13. That is, when the reflecting mask 19 is placed onto the surface of the solid-state photodetector 7, the opening portions 25 will be located directly over the individual photodetecting portions 13. Because of this, the reflecting mask 19 will cover the regions other than the photodetecting portions 13 of the surface of the photodetecting element array 9. The reflecting mask placing step is completed through the placement of the reflecting mask 19.

At this time, the surface of the reflecting mask 19 is not planar, but instead the opening portions 25 are recessed portions. If the light guide were coupled onto the reflecting mask 19 in this form, then the instability of the coupling between the reflecting mask 19 and the light guide would be a concern. That is, the light guide would be bonded with only a small area of the reflecting mask 19, excluding the opening portions 25, so that the adhesive strength between the light guide and the reflecting mask would be extremely weak. The result would be that the reflecting mask 19 and the light guide would delaminate easily.

<Step S4 (Opening Portion Filling Step)>

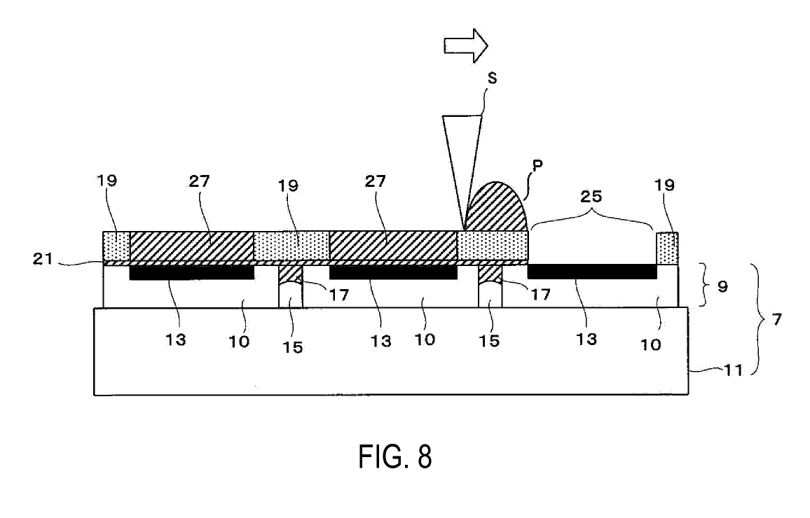

Given this, after the completion of the reflecting mask placement step, a squeegee S is used to fill the opening portions 25 with the high-viscosity adhesive agent P, as illustrated in FIG. 8. The arrow shown in FIG. 8 is the direction of movement of the squeegee S. The high-viscosity adhesive agent P is an adhesive agent wherein optical coupling is possible, where RTV rubber, for example, is used. The high-viscosity adhesive agent P is not only filled into the opening portions 25 to form an opening portion filling layer 27, but also penetrates between the solid-state photodetector 7 and the reflecting mask 19, to form the first adhesive layer 21. This causes the solid-state photodetector 7 and the reflecting mask 19, which were bonded through the adhesive material with a weak adhesive strength in the reflecting mask placing step to be coupled securely through the first adhesive layer 21. The gap portions 15 that are positioned below the first adhesive layer 21 are filled by the gap portion filling layer 17, so no air will pass through the gap portions 15. Because of this, the inclusion of air bubbles in the first adhesive layer 21, from the gap portions 15, is avoided. That is, the scintillator light that is incident into the photodetecting portions 13 is detected, and converted into electric signals, by the photodetecting elements 10, without being scattered by included air bubbles. Moreover, the adhesive strength of the first adhesive layer 21 is not reduced by the inclusion of air bubbles, thus making it possible to avoid delamination of the solid-state photodetector 7 and the reflecting mask 19.

The opening portion filling layer 27 is formed from the high-viscosity adhesive agent in the opening portions 25 by the opening portion filling step. That is, the opening portions 25, which are recessed portions, are filled by the opening portion filling layer 27, so that after the opening portion filling step has been completed, the surface of the reflecting mask 19 will be flat. The gap between the solid-state photodetector 7 and the reflecting mask 19, and the opening portions of 25, are filled with the high-viscosity adhesive agent P, thus completing the opening portion filling step.

<Step S5 (Light Guide Coupling Step)>

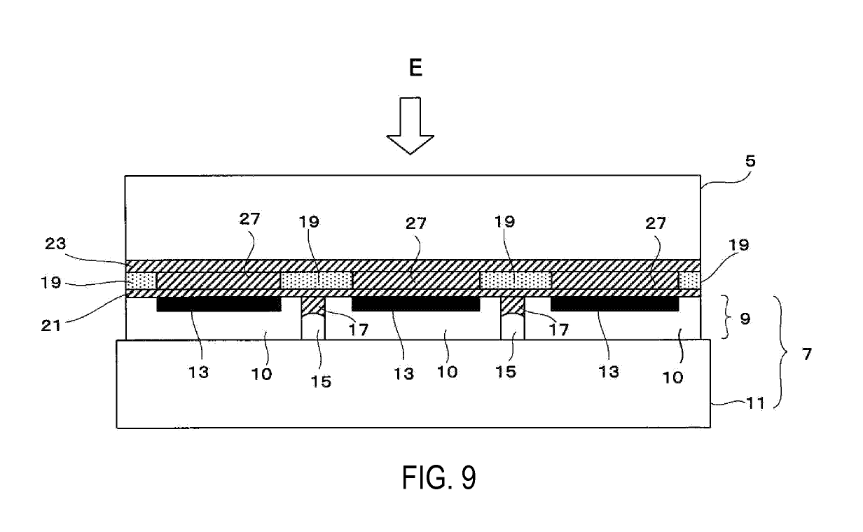

After the completion of the opening portion filling step, the light guide coupling step is started prior to the beginning of curing of the high-viscosity adhesive agent that forms the opening portion filling layer 27. That is, as illustrated in FIG. 9, the light guide 5 and the reflecting mask 19 are coupled by the high-viscosity adhesive agent. The high-viscosity adhesive agent P is an adhesive agent wherein optical coupling is possible, where RTV rubber, for example, is used. A second adhesive layer 23, below the light guide 5, is formed from the high-viscosity adhesive agent, where the light guide 5 and the reflecting mask 19 are bonded securely by the second adhesive layer 23. The opening portions 25 that are positioned below the second adhesive layer 23 are filled by the opening portion filling layer 27, so that there will be no air bubbles included in the second adhesive layer 23 from the opening portions 25.

Moreover, the light guide 5 is transparent, making it possible to ensure visually, or the like, from the direction of the symbol E, shown in FIG. 9, that there are no air bubbles included in the second adhesive layer 23. Consequently, it is possible to avoid more reliably the inclusion of air bubbles in the second adhesive layer 23. That is, the scintillator light that is incident into the photodetecting portions 13 is detected, and converted into electric signals, by the photodetecting elements 10, without being scattered by included air bubbles. Moreover, the adhesive strength of the second adhesive layer 23 is not decreased by the inclusion of air bubbles, thus making it possible to more reliably avoid delamination of the reflecting mask 19 and the light guide 5. The light guide coupling step is completed through coupling the light guide 5 and the reflecting mask 19.

<Step S6 (Scintillator Coupling Step)>

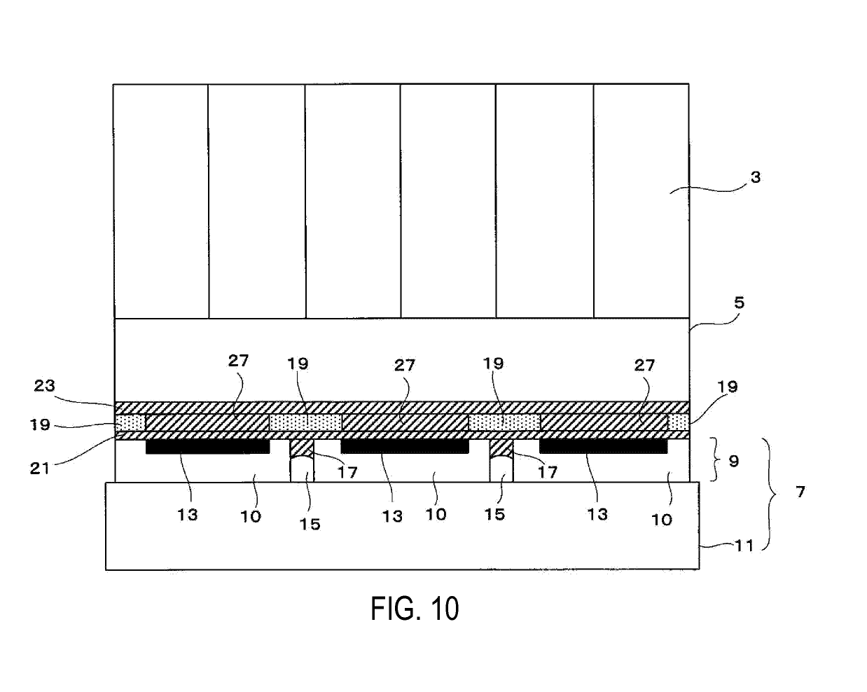

After the light guide coupling step has been completed, then, as illustrated in FIG. 10, the scintillator block 3 and the light guide 5 are optically coupled. Because the scintillator block 3 and the light guide 5 are optically coupled, the scintillator light that is produced by the scintillator block 3 is transmitted by the light guide 5 without loss, to be incident onto the photodetecting portion 13. The scintillator coupling step is completed through optically coupling the scintillator block 3 and the light guide 5.

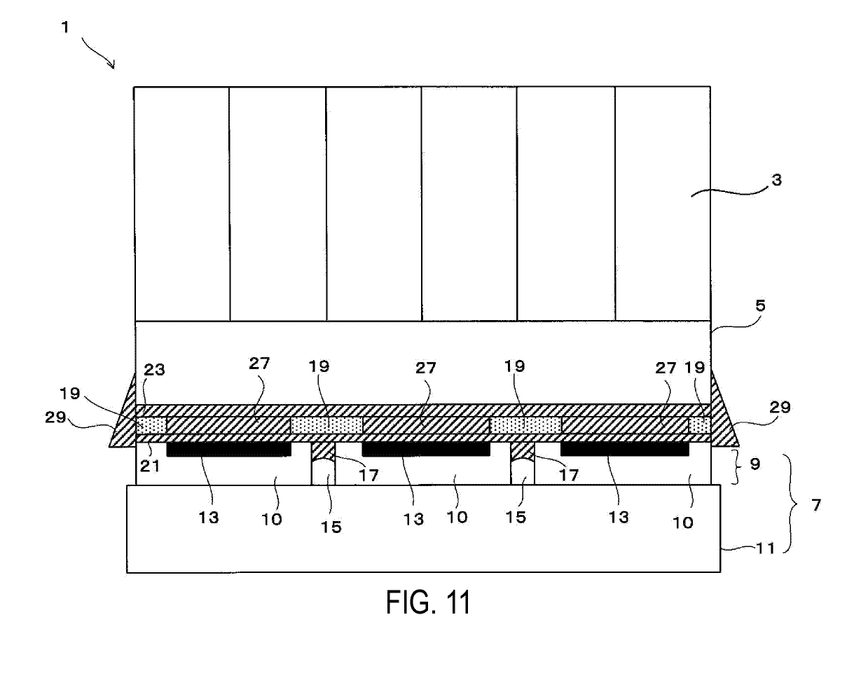

Note that in the light guide coupling step and the scintillator coupling step, a force is applied from above to the high-viscosity adhesive agent through, for example, the weight of the scintillator block. Consequently, a portion of the high-viscosity adhesive agent is forced out from the side peripheral portion of the radiation detector 1 by the force that is applied from above. Given this, the high-viscosity adhesive agent that is forced out forms an adhesive layer coated portion 29 (FIG. 11) on the side peripheral portion of the light guide 5, the side peripheral portion of the reflecting mask 19, and the side peripheral portion of the solid-state photodetector 7. The first adhesive layer 21 and the second adhesive layer 23 are protected from the outside air and moisture by the adhesive layer coated portion 29, and thus a reduction in the adhesive strengths thereof is avoided. Moreover, the adhesive strength between the light guide 5 and the reflecting mask 19, and the adhesive strength between the reflecting mask 19 and the solid-state photodetector 7, are strengthened by the adhesive strength of the adhesive layer coated portion 29 itself. Consequently, delamination of the light guide 5, the reflecting mask 19, and the solid-state photodetector 7 is prevented more reliably by the adhesive layer coated portion 29. Given this, the adhesive layer coated portion 29 is left remaining to the extent that it can cover at least the first adhesive layer 21 and the second adhesive layer 23, rather than the adhesive layer coated portion 29 being removed completely.

<Step S7 (Reflecting Material Coating Step)>

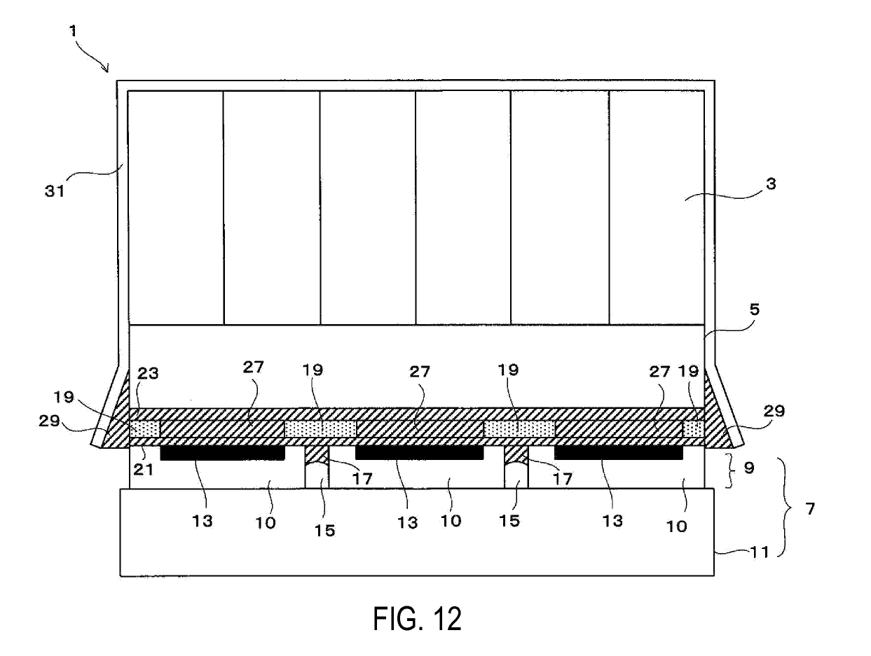

After the scintillator coupling step has been completed then, as illustrated in FIG. 12, a reflecting material 31 is used to coat the side peripheral portion and the top face portion of the scintillator block 3, the side peripheral portion of the light guide 5, and the side peripheral portion of the adhesive layer coated portion 29. The reflecting material 31 is structured from a material that reflects light, such as a fluorine resin, and reflects into the radiation detector 1 scintillator light that is directed to outside of the radiation detector 1. The scintillator light that is reflected to the interior of the radiation detector 1 is ultimately detected by the photodetecting portions 13, to be converted into electric signals. That is, it is possible to avoid the loss of the scintillator light to the outside of the radiation detector 1, and thus the reflecting material 31 enables the scintillator light to be converted efficiently into electric signals.

The reflecting material coating step is completed through completing the coating with the reflecting material 31. Given this, the entire series of steps according to the first embodiment is completed through the completion of the reflecting material coating step.

### Effects of the Structure in the First Embodiment

When, in a radiation detector according to a conventional example, the structure is one wherein photodetecting elements are arrayed two-dimensionally, when the viscosity of the adhesive agent is low, the adhesive agent penetrates to the substrate portion through the gap portions that are formed between the photodetecting elements, producing electrical connection failures. Consequently, radiation detectors manufactured using low-viscosity adhesive agents are unable to stand up to use. On the other hand, when a high-viscosity adhesive agent is used, air bubbles are included in the adhesive agent for coupling the solid-state photodetector and the reflecting mask, and in the adhesive agent for coupling the reflecting mask and the light guide. When air bubbles are included in the adhesive layers, the scintillator light is scattered by the air bubbles, making efficient conversion of the scintillator light into electric signals in the photodetecting portions impossible. Moreover, the couplings of the solid-state detector, the reflecting mask, and the light guide are caused, by the inclusion of the air bubbles, to be weak, and thus the problem of not being able to use the radiation detector under conditions that are prone to the occurrence of delamination has been a concern.

However, in the radiation detector according to the first embodiment, the gap portions formed between the individual photodetecting elements that are arrayed two-dimensionally are filled, in the gap portion filling step, with a high-viscosity adhesive agent used for optical coupling, using RTV rubber as an example. Because of this, the adhesive agent does not penetrate through the gap portions to the substrate portion, and thus there will be no electrical connection defects caused by the adhesive agent. Moreover, because the gap portions are filled with the high-viscosity adhesive agent, air cannot pass through the gap portions. Consequently, there will be no inclusion of air bubbles in the second adhesive layer for coupling the solid-state photodetector and the reflecting mask. That is, there will be no scattering, by air bubbles, of the scintillator light that is incident onto the photodetecting portion through the second adhesive layer, thus making it possible to obtain more accurate imaging information. Moreover, because there is no decrease in the adhesive strength of the second adhesive layer due to the inclusion of air bubbles, the delamination of the solid-state photodetector and the reflecting mask can be prevented more reliably.

Moreover, because, in the adhesive agent removing step, the excess high-viscosity adhesive agent that remains on the surface of the photodetecting element is removed, the surface of the solid-state photodetector is planarized. Consequently, in the reflecting means placing step, the reflecting mask can be placed onto the solid-state photodetector in a more stable state.

Furthermore, in the reflecting means placing step, the reflecting mask is placed onto the solid-state photodetector. Because the reflecting mask is placed so as to cover the parts aside from the photodetecting portions, the scintillator light that is incident onto the photodetecting portions is converted into electric signals, and the scintillator light that is directed to other than the photodetecting portions is reflected. The reflected scintillating light is ultimately incident onto the photodetecting portion, and thus the reflecting mask enables the scintillator light to be converted efficiently into electric signals.

Moreover, in the opening portion filling step, the opening portions of the reflecting mask are filled by a second filling layer, that is, are filled by a high-viscosity adhesive agent that is used for optical coupling.

In the manufacturing method for the radiation detector according to the conventional example, the reflecting mask and the light guide were coupled without filling the opening portions. In this case, the opening portions of the reflecting mask are not bonded to the light guide, and thus the bonding area between the reflecting mask and the light guide is small. The result is that the adhesive strength between the reflecting mask and the light guide is weak, tending to cause delamination between the reflecting mask and the light guide. Moreover, in the manufacturing method according to the conventional example, there is a tendency for air bubbles to be included in the adhesive layer for coupling the reflecting mask and the light guide, and thus there is also the problem of the scintillator light being scattered by the air bubbles.

On the other hand, in the radiation detector manufacturing method according to the first embodiment, the opening portions are filled with the second filling layer in the opening portion filling step. In this case, after the completion of the opening portion filling step, the surface of the reflecting mask is in a flat state, so that the light guide contacts the entire surface of the reflecting mask. That is, the bonding area of the reflecting mask and the light guide is large, so that, in the light guide coupling step, the reflecting mask and the light guide are coupled more securely. Consequently, it becomes possible to manufacture a radiation detector that is highly reliable, even under conditions wherein there is a tendency for delamination to occur.

Moreover, because the opening portions are filled with the second filling layer, no air bubbles will enter into the opening portions after the opening portion filling step. Consequently, in the light guide coupling step the inclusion of air bubbles in the first adhesive layer, through the opening portions, can be avoided more reliably. That is, the scattering, by air bubbles, of the scintillator light that is incident into the photodetecting portions through the first adhesive layer can be prevented, making it possible to obtain more accurate imaging information. Furthermore, because there is no reduction in the adhesive strength of the first adhesive layer due to the inclusion of air bubbles, the delamination of the reflecting mask and the light guide can be prevented more reliably.

Furthermore, in the light guide coupling step, the light guide and the reflecting mask are coupled through the second adhesive layer, that is, through a high-viscosity adhesive agent that is used for optical coupling. At this time, the high-viscosity adhesive agent penetrates into the gap between the reflecting mask and the solid-state photodetector to form the first adhesive layer, thus coupling the reflecting mask and the solid-state photodetector securely. Because the first adhesive layer, the second filling layer, and the second adhesive layer are structured from a high-viscosity adhesive agent that is used for optical coupling, the light guide and the photodetecting portion will be coupled optically. Consequently, the scintillator light that is transmitted through the light guide will be detected, and converted into an electric signal, more reliably by the photodetecting portion.

Moreover, in the scintillator coupling step, the scintillator and the light guide are coupled optically, and thus the optical signal that is converted by the scintillator is detected, and converted into an electric signal, more reliably by the photodetecting portion. Furthermore, in the light guide coupling step and the scintillator coupling step, the high-viscosity adhesive agent is forced out to the side peripheral portion of the radiation detector, and an adhesive layer coated portion is formed from the adhesive agent that is forced out. In the conventional example, typically the adhesive agent that has been forced out has been removed completely in consideration of the visual appearance of the product, adjusting the dimensions, and the like.

On the other hand, in the first embodiment enough of the adhesive layer coated portion is left so as to be able to cover at least the side peripheral portion of the first adhesive layer and the side peripheral portion of the second adhesive layer. The penetration of air and moisture from the outside into the first adhesive layer and the second adhesive layer is prevented by the adhesive layer coated portion. Consequently, a reduction in the adhesive strength of the first adhesive layer and the second adhesive layer is avoided. Moreover, the coupling of the light guide and the reflecting mask and the coupling of the reflecting mask and the solid-state photodetector are further strengthened through the adhesive strength of the adhesive layer coated portion. That is, leaving the adhesive layer coated portion enables the prevention of delamination of the light guide, the reflecting mask, and the solid-state photodetector, thus enabling a further increase in the reliability of the radiation detector.

Furthermore, in the reflecting material coating step, the outer peripheral portion of the radiation detector is coated with a reflecting material that reflects light. The reflecting material reflects, to the interior of the radiation detector, scintillator light that is directed to the outside of the radiation detector. The scintillator light that is reflected to the interior of the radiation detector 1 is ultimately detected by the photodetecting portion and converted into an electric signal. Consequently, this enables efficient conversion of the scintillator light into an electric signal without loss to the outside of the radiation detector.

As described above, the inventive concept according to the first embodiment is able to produce the effect of causing the optical coupling in the radiation detector to be more secure in a radiation detector that incorporates a SiPM element. That is, the conventional problem wherein there is a tendency for delamination to occur due to the optical coupling of the detector becoming weak due to the plurality of SiPM elements being arrayed two-dimensionally is solved.

When SiPM elements are used as the photodetecting elements, it is envisioned that the radiation detector be used in a temperature range of between, for example, −20° C. and +25° C., in order to suppress noise that is produced within the photodetecting elements. That is, the radiation detector is to be used under conditions wherein there will be a tendency for the adhesive strengths to be reduced and for the components to become delaminated from each other due to the effect of thermal expansion due to temperature differentials.

That is, the radiation detector according to the present disclosure has extremely secure optical coupling, thus enabling use even under conditions wherein one would expect the adhesive strength to be reduced, as described above. Because a SiPM element is not affected by the strong magnetic fields that are produced by the MR device, the radiation detector according to the present disclosure can be used in a PET-MR. Consequently, it is possible to achieve a PET-MR that has secure optical coupling, and that can be used even under conditions wherein there will be little noise.

### Embodiment 2

A radiation detector 1A, and a radiation detector 1A manufacturing method, according to a second embodiment according to the present disclosure will be explained next in reference to the drawings. Note that those structures in the radiation detector 1A that are identical to those in the radiation detector 1, described above, are assigned identical codes, and detailed explanations thereof are omitted.

### Distinctive Structures of the Second Embodiment

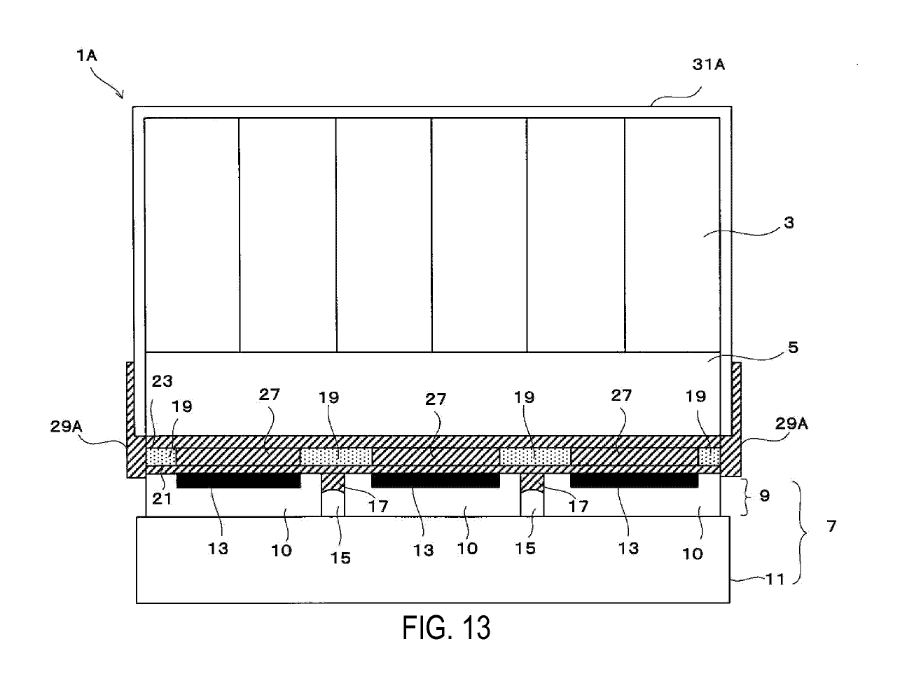

As illustrated in FIG. 13, the radiation detector 1A according to a second embodiment has a structure wherein a scintillator block 3, a light guide 5, a reflecting mask 19, and a solid-state photodetector 7 are layered, from the top down, in the sequence set forth above. The side peripheral portion and the top face portion of the scintillator block 3 and the side peripheral portion of the light guide 5 are coated tightly by a reflecting material 31A that reflects light. The reflecting material 31A reflects toward the interior of the radiation detector 1A light that is emitted from the scintillator block 3 and that is directed toward the outside of the radiation detector 1A.

An adhesive layer coated portion 29A is provided on the side peripheral portion of the reflecting material 31A, the solid-state photodetector 7, and the reflecting mask 19. The adhesive layer coated portion 29A is structured from a high-viscosity adhesive agent, with RTV rubber as an example, further strengthening the optical couplings between the light guide 5, the reflecting mask 19, and the solid-state photodetector 7.

### Explanation of the Distinctive Steps in the Second Embodiment

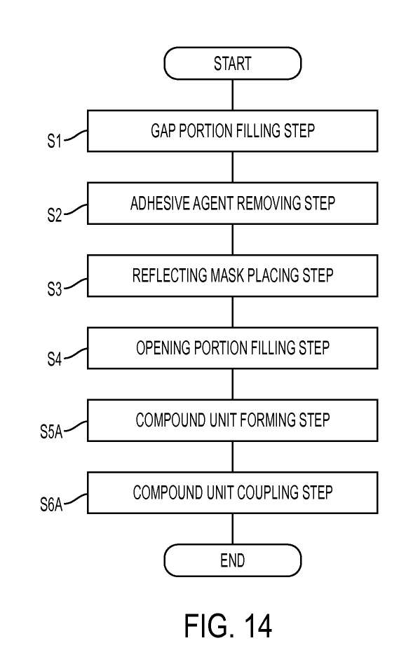

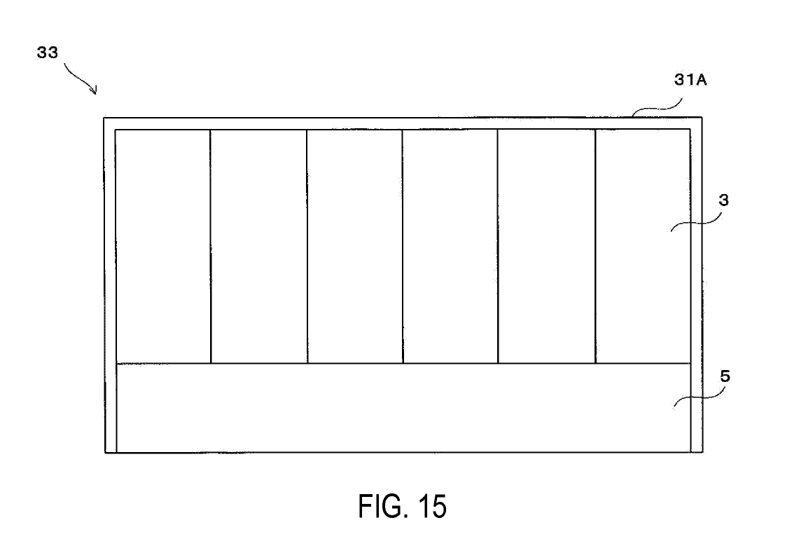

The steps in a method for manufacturing a radiation detector 1A, structured as described above, will now be explained with reference to FIG. 14 through FIG. 17. FIG. 14 is a flowchart for explaining the steps in the radiation detector manufacturing method according to the second embodiment, and FIG. 15 through FIG. 17 are vertical sectional diagrams illustrating schematic structures in the distinctive manufacturing steps in the method for manufacturing the radiation detector according to the second embodiment.

As illustrated in FIG. 3 and FIG. 14, in the steps according to the second embodiment, the steps from Step S1 through Step S4 are the same as the steps in the first embodiment, described above. Because of this, detailed explanations will be omitted for Step S1 through Step S4, and the steps, Step S5A and Step S6A, that are distinctive to the second embodiment will be explained.

<Step S5A (Compound Unit Forming Step)>

As illustrated in FIG. 8, in Step S4, that is, in the opening portion filling step, the opening portions 25 were filled by an opening portion filling layer 27, causing the surface of the reflecting mask 19 to be flat. As described above, in the first embodiment the light guide coupling step was performed after the completion of the opening portion filling step.

On the other hand, in the second embodiment, after the completion of the opening portion filling step a compound unit forming step is performed. That is, as illustrated in FIG. 15, first the light guide 5 and the scintillator block 3 are optically coupled using the high-viscosity adhesive agent. Because the light guide 5 and the scintillator block 3 are optically coupled, the scintillator light that is emitted from the scintillator block 3 is transmitted efficiently by the light guide 5.

Given this, the side peripheral portion and the top face portion of the scintillator block 3, and the side peripheral portion of the light guide 5 are coated with a reflecting material 31A. The compound unit that is the scintillator block 3, the light guide 5, and the reflecting material 31A, formed through the compound unit forming step, is referred to below as a scintillator compound unit 33. The reflecting material 31A is structured from a material that reflects light, such as a fluorine resin, and reflects into the interior of the radiation detector 1A light that is emitted from the scintillator block 3 and that is directed to the outside of the radiation detector 1A. The scintillator compound unit forming step is completed by the formation of the scintillator compound unit 33.

<Step S6A (Compound Unit Coupling Step)>

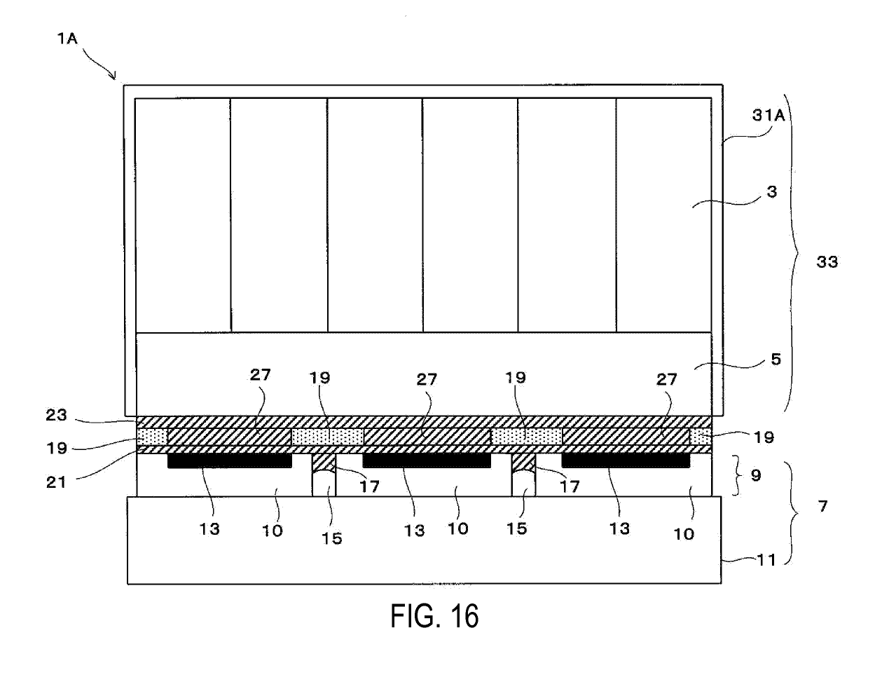

After the opening portion filling step and the compound unit forming step have been completed, then, as illustrated in FIG. 16, the light guide 5 side face of the scintillator compound unit 33 and the reflecting mask 19 are coupled using the high-viscosity adhesive agent. A second adhesive layer 23, below the light guide 5, is formed from the high-viscosity adhesive agent, where the light guide 5 and the reflecting mask 19 are bonded securely by the second adhesive layer 23. The opening portions 25 that are positioned below the second adhesive layer 23 are filled by the opening portion filling layer 27, so that there will be no air bubbles included in the second adhesive layer 23 from the opening portions 25. The result is that there will be no decrease in adhesive strength due to the inclusion of air bubbles, making it possible to prevent delamination of the light guide 5 and the reflecting mask 19.

Moreover, the light guide 5 and the photodetecting portion 13 are optically coupled by the high-viscosity adhesive agent that forms the first adhesive layer, the second adhesive layer, and the opening portion filling layer 27. Because of this, the scintillator light that is transmitted by the light guide 5 is detected, and converted into an electric signal, more accurately by the photodetecting portion 13.

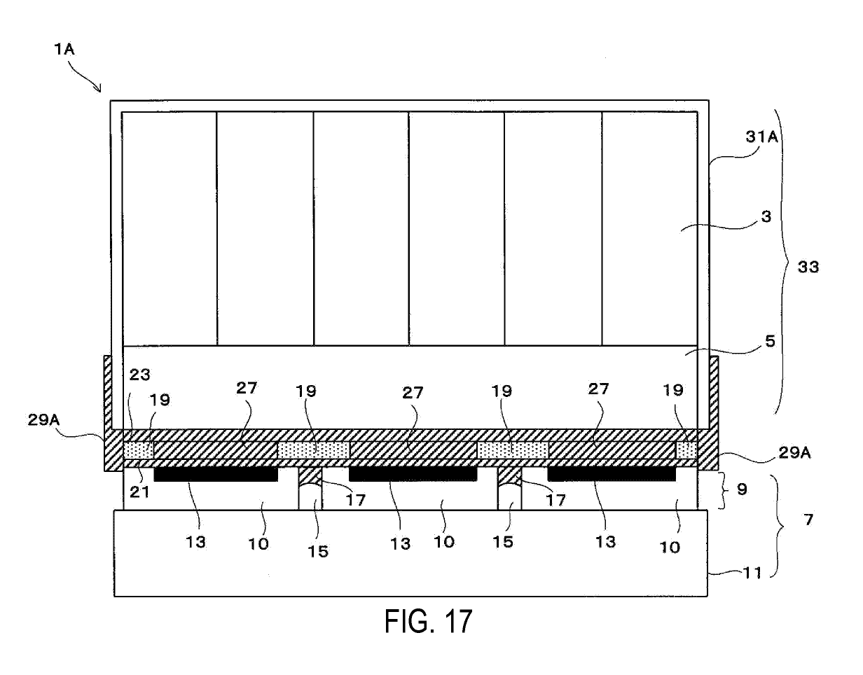

In the compound unit coupling step, as illustrated in FIG. 17, a portion of the high-viscosity adhesive agent is forced out to the side peripheral portion of the radiation detector 1A by the weight of the scintillator compound unit 33, and the like. Given this, an adhesive layer coated portion 29A is formed on the respective side peripheral portions of the reflecting material 31A, the reflecting mask 19, and the solid-state photodetector 7 from the high-viscosity adhesive agent that is forced out. The first adhesive layer 21 and the second adhesive layer 23 are protected from air and moisture from the outside by the adhesive layer coated portion 29A. Moreover, the coupling of the light guide 5 and the reflecting mask 19 and the coupling of the reflecting mask 19 and the solid-state photodetector 7 are strengthened by the adhesive strength of the adhesive layer coated portion 29A.

Moreover, the adhesive layer coated portion 29A is left to a degree that it is able to coat at least the side peripheral portions of the first adhesive layer 21 and the second adhesive layer 23. The compound unit coupling step is completed through the coupling of the scintillator compound unit 33 and the reflecting mask 19, and through the formation of the adhesive layer coated portion 29A. Given this, the entire series of steps in the radiation detector 1A manufacturing method is completed through the completion of the compound unit coupling step.

### Effects of the Distinctive Steps in the Second Embodiment

In this way, in the manufacturing method for the radiation detector according to the second embodiment, first a scintillator compound unit is formed by coupling the light guide, the scintillator block, and the reflecting material in the compound unit forming step. Following this, the radiation detector is completed by optically coupling the solid-state photodetector, on which the reflecting mask is placed, and the scintillator compound unit in the compound unit coupling step.

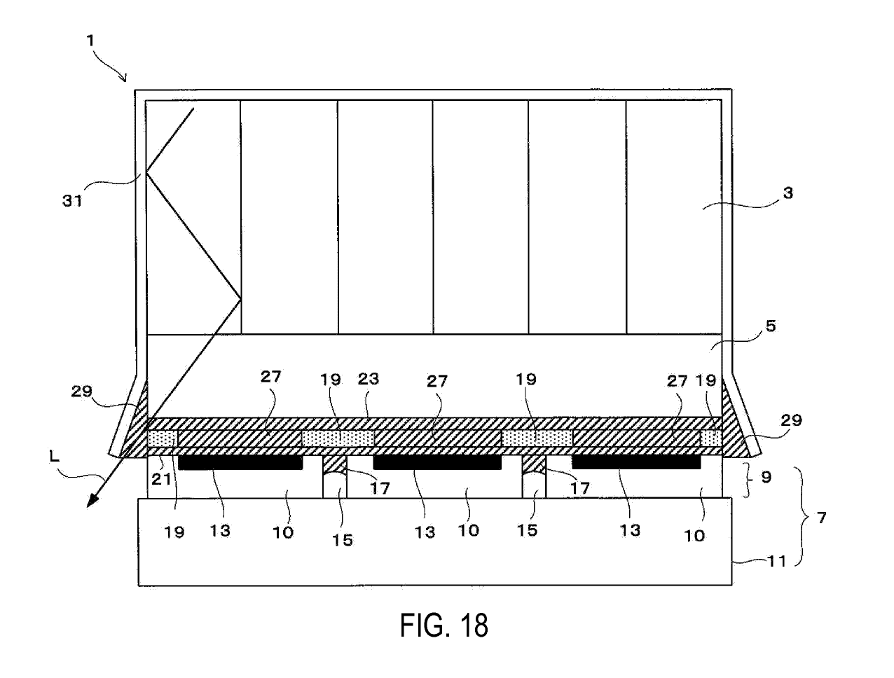

In the manufacturing method for a radiation detector according to the first embodiment, the reflecting material coating step was performed after the formation of the adhesive layer coated portion, and thus the structure is one where the reflecting material is coated on the outside of the adhesive layer coated portion. In other words, the reflecting material is not coated tightly on the light guide, but rather the adhesive layer coated portion exists between the light guide and the reflecting material. Because of this, as illustrated in FIG. 18, a portion of the scintillator light (indicated by the code L) is not reflected by the reflecting material 31, but rather the leaks to the outside of the radiation detector 1 through the adhesive layer coated portion 29.

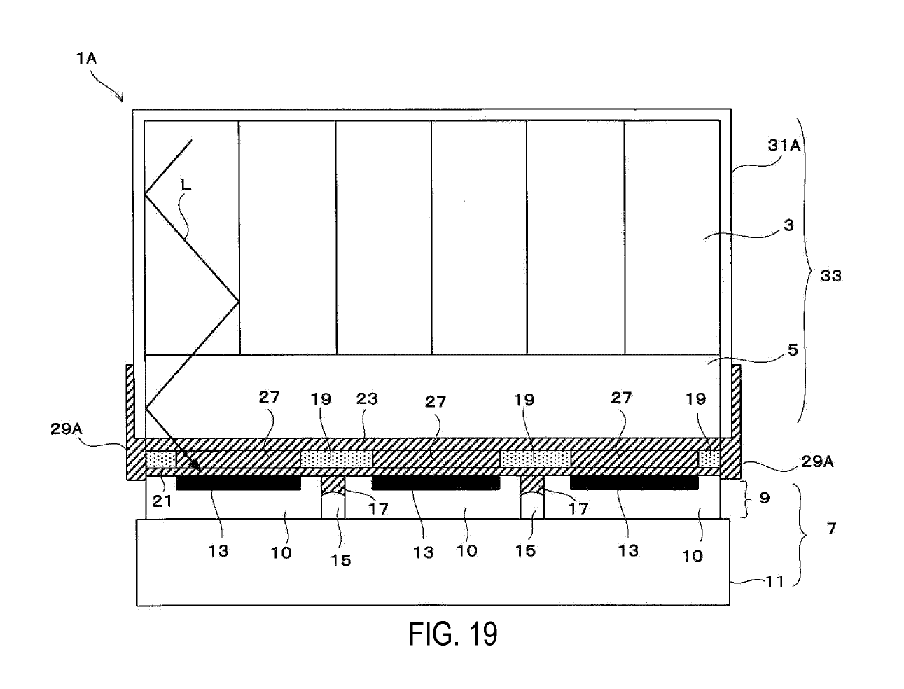

However, in the radiation detector according to the second embodiment, the reflecting material is coated tightly onto the light guide in the compound unit coupling step prior to the formation of the adhesive layer coated portion. Consequently, as illustrated in FIG. 19, all of the scintillator light L that is directed towards the outside of the radiation detector 1A is reflected by the reflecting material 31A. In other words, the scintillator light L is all ultimately incident onto the photodetecting portion 13 and converted into an electric signal. Consequently, the radiation detector according to the second embodiment is able to convert the scintillator light into electric signals more efficiently.

The present inventive concept is not limited to the embodiments set forth above, but rather modified embodiments, such as described below, are also possible.

While in the respective embodiments set forth above a fluorine resin was used for the reflecting materials 31 and 31A, there is no limitation thereto. For example, a material that not only has the property of reflecting light, but that also has the property of adhering securely to a high-viscosity adhesive agent that performs optical coupling, such as a white plastic film, or the like, may be used instead. The use, as the reflecting material 31 and 31A, of a material that adheres securely to the high-viscosity adhesive agent will further strengthen the bond of the adhesive layer coated portion 29 or 29A, which is formed from the high-viscosity adhesive agent, to the reflecting material 31 or 31A. Consequently, this makes it possible to increase the reliability of the radiation detector 1 according to the first embodiment or the radiation detector 1 A according to the second embodiment.

While in the individual embodiments, set forth above, SiPM elements were used as the photodetecting elements 10, there is no limitation thereto, and an APD element may be used instead. The APD element, like the SiPM element, is resistant to the effects of a magnetic field, and a PET device that uses APD elements as the photodetecting elements 10 can be combined with an MR device to form a PET-MR. Moreover, the PET-MR can be used to obtain images of the subject body that are well-suited to both biological functional diagnostics and anatomical diagnostics.

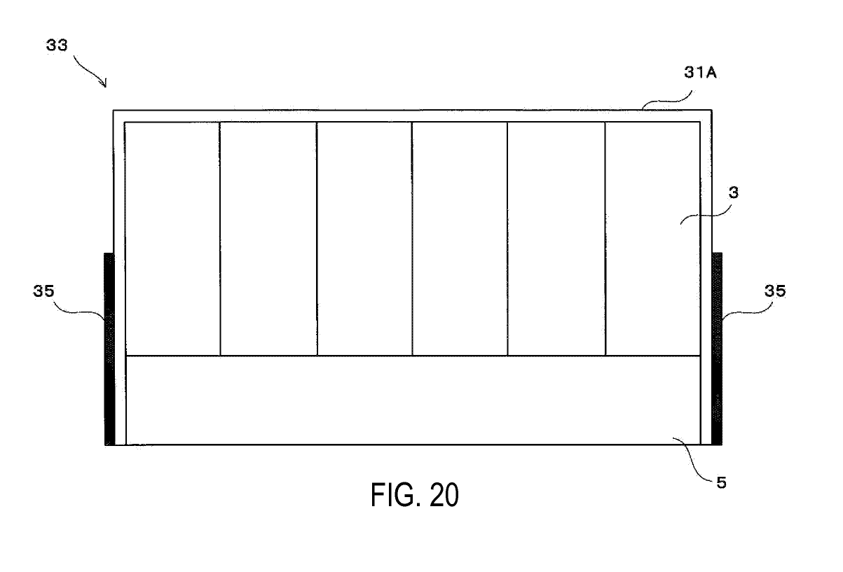

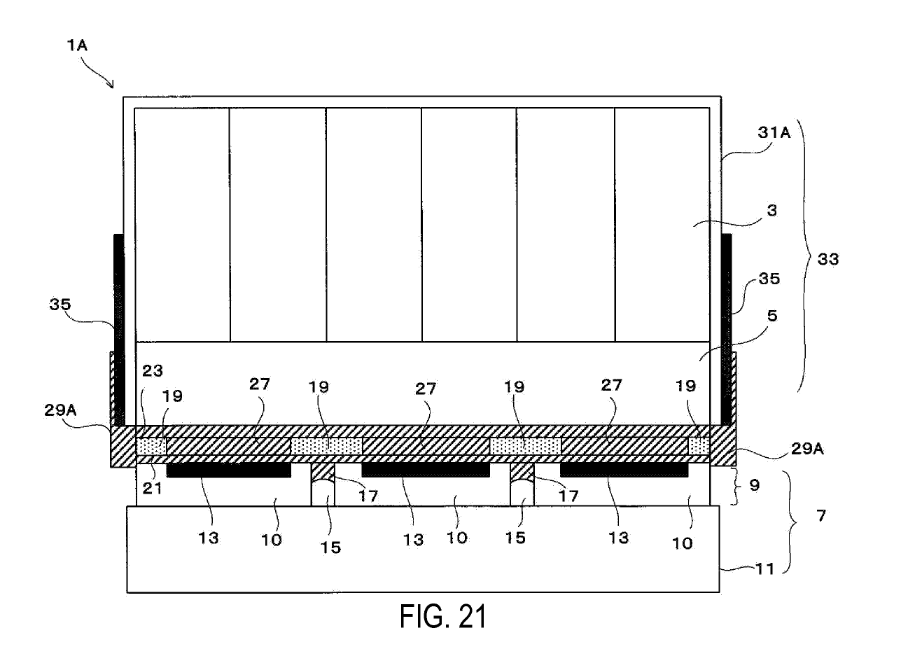

While in the second embodiment, set forth above, the scintillator compound unit 33 was structured through the scintillator block 3 and the light guide 5 being coated with the reflecting material 31A, there is no limitation thereto. That is, as illustrated in FIG. 20, an adhesion strengthening material 35 may also be coated on the outside of the reflecting material 31A. The adhesion strengthening material 35 is a material that bonds securely to the high-viscosity adhesive agent P that is used for optical coupling. Because of this, when, as illustrated in FIG. 21, the scintillator compound unit 33 and the reflecting mask 19 are coupled, the adhesive layer coated portion 29A that is structured from the high-viscosity adhesive agent is bonded more securely to the reflecting material 31A through the adhesion strengthening material 35. Consequently, the optical coupling of the radiation detector 1A is made more secure.

While in the second embodiment set forth above the compound unit forming step was performed following the opening portion filling step, to form the scintillator compound unit, there is no limitation thereto. Insofar as the scintillator compound unit is formed prior to the compound unit coupling step, the compound unit forming step may be performed at any time. Performing the compound unit forming step with the appropriate timing makes it possible to perform the various steps according to the present disclosure more efficiently.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A radiation detector comprising:
a scintillator block for detecting incident radiation and emitting light;
a light guide, optically coupled to the scintillator block, for transmitting light emitted from the scintillator block;
a solid-state photodetector, wherein a plurality of photodetecting elements for converting, into electric signals, light that is transmitted from the light guide, is arrayed in a two-dimensional matrix, and is optically coupled to the light guide;
a reflector for reflecting light, disposed between the light guide and the solid-state photodetector, and having opening portions in positions facing the photodetecting portions of the photodetecting elements;
a first adhesive layer for bonding the reflector and the solid-state photodetector;
a first filling layer for filling a gap portion between the photodetecting elements;
a second adhesive layer for bonding the light guide and the reflector; and
a second filling layer for filling an opening portion that is provided in the reflector.

2. The radiation detector as set forth in claim 1, further comprising:
an adhesive layer coated portion, structured from an adhesive agent used for optical coupling, coating, in tight contact, a side peripheral portion of the first adhesive layer and a side peripheral portion of the second adhesive layer; and
a reflecting material for reflecting light, coating, in tight contact, the scintillator block, the light guide, the solid-state photodetector, and the adhesive layer coated portion.

3. The radiation detector as set forth in claim 1, further comprising:
a reflecting material for reflecting light, coating, in tight contact, a side peripheral portion and a top face portion of the scintillator block and a side peripheral portion of the light guide.

4. The radiation detector as set forth in claim 3, further comprising:
an adhesive layer coated portion, structured from an adhesive agent used for optical coupling, coating, in tight contact, respective side peripheral portions of the first adhesive layer, the second adhesive layer, and the reflecting material.

5. The radiation detector as set forth in claim 3, further comprising:
an adhesion strengthening material, coating, in tight contact, a side peripheral portion of the reflecting material, adhered to the adhesive agent used for optical coupling.

6. The radiation detector as set forth in claim 5, wherein the reflecting material is a material that bonds to the adhesive agent that is used for optical coupling.

7. The radiation detector as set forth in claim 6, wherein the photodetecting element is a SiPM element or an APD element.

8. A method for manufacturing a radiation detector, the method comprising steps of a gap filling step for filling, with an adhesive agent that is used for optical coupling, a gap portion that is provided between photodetecting elements that structure a solid-state photodetector;
an adhesive agent removing step for removing an adhesive agent that remains on the surface of the solid-state photodetector after the gap portion filling step;
a reflecting mask placing step for placing, onto a surface of the solid-state photodetector, a reflecting mask that is provided with an opening portion in a position facing a photodetecting portion of a photodetecting element, after the adhesive agent removing step;
an opening portion filling step, after the reflecting mask placing step, for filling an opening portion, provided in the reflecting mask, with an adhesive agent used for optical coupling, and also for coupling the solid-state photodetector and the reflecting mask;
a light guide coupling step, after the opening portion filling step, for coupling the light guide and the reflecting mask; and
a scintillator coupling step, after the light guide coupling step, for optically coupling the scintillator block and the light guide.

9. The radiation detector manufacturing method as set forth in claim 8, further including the step of:
a reflecting material coating step, after the scintillator coupling step, for leaving at least a portion of an adhesive agent that is forced out to the side peripheral portions of the light guide, the reflecting mask, and the solid-state photodetector, and coating, with a reflecting material that reflects light, the respective side peripheral portions of the scintillator block, the light guide, the solid-state photodetector, and the remaining adhesive agent.

10. A method for manufacturing a radiation detector, the method comprising steps of
a gap filling step for filling, with an adhesive agent that is used for optical coupling, a gap portion that is provided between photodetecting elements that structure a solid-state photodetector;
an adhesive agent removing step for removing an adhesive agent that remains on the surface of the solid-state photodetector after the gap portion filling step;
a reflecting mask placing step for placing, onto a surface of the solid-state photodetector, a reflecting mask that is provided with an opening portion in a position facing a photodetecting portion of a photodetecting element, after the adhesive agent removing step;
an opening portion filling step, after the reflecting mask placing step, for filling an opening portion, provided in the reflecting mask, with an adhesive agent used for optical coupling, and also for coupling the solid-state photodetector and the reflecting mask;
a compound unit forming step for optically coupling the scintillator block and the light guide to form a scintillator compound unit wherein the side peripheral portion and the top face portion of the scintillator block and the side peripheral portion of the light guide are coated with a reflecting material of that reflects light; and
a compound unit coupling step, after the opening portion filling step and the compound unit forming step, for coupling the scintillator compound unit and the reflecting mask.

11. The radiation detector manufacturing method as set forth in claim 10, wherein at least a portion of the adhesive agent that is forced out to the respective side peripheral portions of the scintillator compound unit, the reflecting mask, and the solid-state photodetector is left remaining.

12. The radiation detector manufacturing method as set forth in claim 8, further comprising a material that is adhered to the adhesive agent that is used for optical coupling, on a side peripheral portion of the scintillator compound unit.

13. The radiation detector manufacturing method as set forth in claim 8, wherein the reflecting material is a material that is bonded to the adhesive agent that is used in optical coupling.

14. The radiation detector manufacturing method as set forth in claim 8, wherein the photodetecting element is a SiPM element or an APD element.

15. The radiation detector manufacturing method as set forth in claim 10, further comprising a material that is adhered to the adhesive agent that is used for optical coupling, on a side peripheral portion of the scintillator compound unit.

16. The radiation detector manufacturing method as set forth in claim 10, wherein the reflecting material is a material that is bonded to the adhesive agent that is used in optical coupling.

17. The radiation detector manufacturing method as set forth in claim 10, wherein the photodetecting element is a SiPM element or an APD element.
